(19) United States
(12) Patent Application Publication
(10) Pub. No.: US 2025/0260507 A1
(43) Pub. Date: Aug. 14, 2025

(54) COMMUNICATION METHOD AND APPARATUS

(71) Applicant: HUAWEI TECHNOLOGIES CO., LTD., Shenzhen (CN)

(72) Inventors: Jiahui LI, Shenzhen (CN); Mengyao MA, Shenzhen (CN); Yan CHEN, Ottawa (CA)

(73) Assignee: HUAWEI TECHNOLOGIES CO., LTD., Shenzhen (CN)

(21) Appl. No.: 19/193,367

(22) Filed: Apr. 29, 2025

Related U.S. Application Data
(63) Continuation of application No. PCT/CN2022/128662, filed on Oct. 31, 2022.

(51) Int. Cl. H04L 1/00; H03M 13/35

(52) U.S. Cl. CPC H04L 1/0005; H03M 13/356; H04L 2001/0098

(57) ABSTRACT

This application relates to the field of communication technologies, and discloses a communication method and apparatus. The method includes: performing layering on first data, to obtain N layers of data, where N is an integer greater than or equal to 2; receiving modulation and coding indication information from a second communication apparatus, where the modulation and coding indication information indicates an MCS corresponding to each layer of data in P layers of data, the P layers of data belong to the N layers of data, and the MCS corresponding to each layer of data in the P layers of data; and separately performing coding and modulation on the P layers of data based on the MCS corresponding to each layer of data in the P layers of data.

### CROSS REFERENCE TO RELATED APPLICATIONS

This application is a continuation of International Application No. PCT/CN2022/128662, filed on Oct. 31, 2022, the disclosure of which is hereby incorporated by reference in its entirety.

### TECHNICAL FIELD

This application relates to the field of communication technologies, and in particular, to a communication method and apparatus.

### BACKGROUND

With rapid development of industries such as environment sensing, imaging, artificial intelligence (artificial intelligence, AI), and machine learning (machine learning, ML), an explosive data volume poses new challenges to network transmission capabilities. Currently, to improve data transmission performance, in one manner, a retransmission mechanism is introduced, and data retransmission is performed when resources are available, so that more data is correctly transmitted; and in another manner, unequal error protection (unequal error protection, UEP), also referred to as unequal protection, is introduced, and more robust channel protection is performed on important data, to ensure that a receiver can correctly decode the important data when channel quality fluctuates. Compared with the retransmission mechanism for data retransmission, the UEP has advantages of a lower transmission delay and lower resource overheads, and can be better adapted to real-time transmission and fusion of data in sensing, imaging, AI, ML, and the like.

However, the current UEP is mainly adapted to a multiple-input multiple-output (multiple-input multiple-output, MIMO) technology. Different modulation and coding schemes (modulation and coding scheme, MCS) are configured for different MIMO streams, to adapt to transmission quality requirements of the different MIMO streams. Only a transmission quality requirement per MIMO stream is considered, and a transmission quality requirement of single data is not considered, resulting in low flexibility and inapplicability to a non-MIMO scenario.

### SUMMARY

This application provides a communication method and apparatus, to improve data transmission flexibility and transmission performance by performing UEP layered transmission on to-be-transmitted data, and support UEP data transmission in a non-MIMO scenario.

According to a first aspect, an embodiment of this application provides a communication method. The method may be performed by a first communication apparatus, and the method includes: performing layering on first data, to obtain N layers of data, where N is an integer greater than or equal to 2; receiving modulation and coding indication information from a second communication apparatus, where the modulation and coding indication information indicates an MCS corresponding to each layer of data in P layers of data, the P layers of data belong to the N layers of data, the MCS corresponding to each layer of data in the P layers of data is determined based on a ranking of a source contribution degree of the layer of data in the P layers of data and a policy of mapping between a source contribution degree ranking and an MCS, the source contribution degree of each layer of data in the P layers of data indicates a deviation caused to the first data when the layer of data is missing, and P is less than or equal to N; separately performing coding and modulation on the P layers of data based on the MCS corresponding to each layer of data in the P layers of data, to obtain P bitstreams; and sending N bitstreams to the second communication apparatus, where the N bitstreams include the P bitstreams and N—P bitstreams corresponding to N—P layers of data other than the P layers of data in the N layers of data. Optionally, the method further includes: sending source characteristic information to the second communication apparatus, where the source characteristic information includes the source contribution degree of each layer of data in the P layers of data.

In the foregoing communication method, the first communication apparatus may be a terminal device, a component (for example, a processor, a chip, or a chip system) of the terminal device, an apparatus that matches the terminal device for use, or the like. The second communication apparatus may be a network device, a component (for example, a processor, a chip, or a chip system) of the network device, an apparatus that matches the network device for use, or the like. Alternatively, the first communication apparatus may be a terminal device, a component of the terminal device, an apparatus that matches the terminal device for use, or the like, and the second communication apparatus is a terminal device different from the first communication apparatus, a component of the terminal device, or an apparatus that matches the terminal device for use.

According to the foregoing method, UEP layering is performed on to-be-transmitted data, a source contribution degree of each layer of data is determined, and an importance degree of each layer of data is indicated, so that the second communication apparatus can configure an MCS for each layer of data based on the source contribution degree (that is, the importance degree) of each layer of data, and different data layers in the data can use MCSs with different protection degrees. This can satisfy a transmission quality requirement per data, and improve transmission flexibility and overall data transmission robustness. In addition, UEP transmission of data in a single transport stream in a non-MIMO scenario is supported, so that an application scope of UEP transmission can be improved.

In a possible design, the performing layering on first data, to obtain N layers of data includes: determining, based on a first data type of the first data and an association relationship between a data type and a layering mode, a first layering mode associated with the first data type; and performing layering on the first data in the first layering mode, to obtain the N layers of data.

Optionally, the deviation caused to the first data when each layer of data in the P layers of data is missing includes: one or more of a mean square error, a normalized mean square error, an imaging error, a positioning error, and an inference error caused to the first data when each layer of data in the P layers of data is missing.

In the foregoing design, corresponding layering is performed on the first data based on the data type of the first data, and a corresponding deviation calculation manner is used, so that data of different data types can be flexibly adapted to, thereby helping improve transmission performance.

In a possible design, that the MCS corresponding to each layer of data in the P layers of data is determined based on a ranking of a source contribution degree of the layer of data in the P layers of data and a policy of mapping between a source contribution degree ranking and an MCS includes: The MCS corresponding to each layer of data in the P layers of data is determined based on channel state information with the second communication apparatus, the ranking of the source contribution degree of the layer of data in the P layers of data, and a policy of mapping between an MCS and both channel state information and a source contribution degree ranking.

In the foregoing design, when the MCS corresponding to each layer of data is determined, the channel state information between the first communication apparatus and the second communication apparatus may be further considered, to further improve transmission reliability.

In a possible design, the method further includes: sending data length information of each layer of data in the N layers of data to the second communication apparatus; and receiving resource configuration information from the second communication apparatus, where the resource configuration information is used to configure M transport blocks TBs for transmitting the N layers of data, and M is an integer greater than or equal to 1; and the sending N bitstreams to the second communication apparatus includes: sending the N bitstreams to the second communication apparatus on the M TBs.

In the foregoing design, the data length information of each layer of data in the N layers of data is reported to the second communication apparatus, so that the second communication apparatus can determine, based on the data length information and the MCS of each layer of data in the N layers of data, resources required for transmitting the N bitstreams corresponding to the N layers of data, to accurately configure resources for transmitting the N layers of data, so that resource utilization can be improved, and a resource waste can be reduced.

In a possible design, when a quantity O of transport streams for transmitting the N layers of data is greater than or equal to 2, the sending the N bitstreams to the second communication apparatus on the M TBs includes: dividing the N bitstreams into O groups of bitstreams based on sizes of the N bitstreams, where a difference between data volumes of the O groups of bitstreams is minimized; and respectively sending the O groups of bitstreams to the second communication apparatus on the M TBs through the O transport streams.

In the foregoing design, the N bitstreams are divided into the O groups of bitstreams, and the difference between the data volumes of the O groups of bitstreams is minimized, so that load of the O transport streams can be balanced, and transmission efficiency can be improved.

In a possible design, the method further includes: receiving layer quantity indication information from the second communication apparatus, where the layer quantity indication information indicates N; or determining N based on a UEP requirement for transmitting the first data.

In a possible design, MCSs corresponding to any two layers of data in the P layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

In the foregoing design, compared with the layered data corresponding to the smaller source contribution degree, the layered data corresponding to the larger source contribution degree may use a lower code rate and/or modulation order. This helps improve transmission robustness of the layered data corresponding to the larger source contribution degree, and ensure transmission performance.

According to a second aspect, an embodiment of this application provides a communication method. The method may be performed by a second communication apparatus, and the method includes: obtaining a source contribution degree of each layer of data in P layers of data in first data to be sent by a first communication apparatus, where the source contribution degree of each layer of data in the P layers of data indicates a deviation caused to the first data when the layer of data is missing; and sending modulation and coding indication information to the first communication apparatus, where the modulation and coding indication information indicates an MCS corresponding to each layer of data in the P layers of data, and the MCS corresponding to each layer of data in the P layers of data is determined based on a ranking of the source contribution degree of the layer of data in the P layers of data and a policy of mapping between a source contribution degree ranking and an MCS.

In the foregoing communication method, the first communication apparatus may be a terminal device, a component (for example, a processor, a chip, or a chip system) of the terminal device, an apparatus that matches the terminal device for use, or the like. The second communication apparatus may be a network device, a component (for example, a processor, a chip, or a chip system) of the network device, an apparatus that matches the network device for use, or the like. Alternatively, the first communication apparatus may be a terminal device, a component of the terminal device, an apparatus that matches the terminal device for use, or the like, and the second communication apparatus is a terminal device different from the first communication apparatus, a component of the terminal device, or an apparatus that matches the terminal device for use.

In a possible design, the method further includes: receiving N bitstreams from the first communication apparatus, where the N bitstreams correspond to N layers of data in the first data, the N layers of data include the P layers of data, the N bitstreams include P bitstreams corresponding to the P layers of data and N—P bitstreams corresponding to N—P layers of data other than the P layers of data in the N layers of data, N is an integer greater than or equal to 2, and P is less than or equal to N; demodulating and decoding the N bitstreams, to obtain the N layers of data, where the P bitstreams corresponding to the P layers of data in the N bitstreams are demodulated and decoded based on the MCS corresponding to each layer of data in the P layers of data; and reconstructing the N layers of data, to obtain the first data.

In a possible design, the obtaining a source contribution degree of each layer of data in P layers of data to be sent by a first communication apparatus includes: receiving source characteristic information from the first communication apparatus, where the source characteristic information includes the source contribution degree of each layer of data in the P layers of data.

In a possible design, the deviation caused to the first data when each layer of data in the P layers of data is missing includes: one or more of a mean square error, a normalized mean square error, an imaging error, a positioning error, and an inference error caused to the first data when each layer of data in the P layers of data is missing.

In a possible design, that the MCS corresponding to each layer of data in the P layers of data is determined based on a ranking of the source contribution degree of the layer of data in the P layers of data and a policy of mapping between a source contribution degree ranking and an MCS includes: The MCS corresponding to each layer of data in the P layers of data is determined based on channel state information with the first communication apparatus, the ranking of the source contribution degree of the layer of data in the P layers of data, and a policy of mapping between an MCS and both channel state information and a source contribution degree ranking.

In a possible design, the method further includes: receiving data length information of each layer of data in the N layers of data from the first communication apparatus; determining, based on the data length information of each layer of data in the N layers of data, the MCS corresponding to each layer of data in the P layers of data in the N layers of data, and MCSs corresponding to the N—P layers of data, sizes of the N bitstreams corresponding to the N layers of data; determining, based on the sizes of the N bitstreams corresponding to the N layers of data and a quantity O of transport streams for transmitting the N layers of data, M transport blocks TBs for transmitting the N layers of data, where M and O are integers greater than or equal to 1; and sending resource configuration information to the first communication apparatus, where the resource configuration information is used to configure the M TBs; and the receiving N bitstreams from the first communication apparatus includes: receiving the N bitstreams from the first communication apparatus on the M TBs.

In a possible design, the determining, based on the sizes of the N bitstreams corresponding to the N layers of data and a quantity O of transport streams for transmitting the N layers of data, M TBs for transmitting the N layers of data includes: dividing the N bitstreams into O groups of bitstreams based on the sizes of the N bitstreams corresponding to the N layers of data, where a difference between data volumes of the O groups of bitstreams is minimized; and determining, based on a data volume of a group of bitstreams corresponding to a largest data volume in the O groups of bitstreams, the M TBs for transmitting the N layers of data.

In a possible design, the method further includes: determining N based on a UEP requirement for transmitting the first data by the first communication apparatus; and sending layer quantity indication information to the first communication apparatus, where the layer quantity indication information indicates N.

In a possible design, MCSs corresponding to any two layers of data in the P layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

According to a third aspect, an embodiment of this application provides a communication method. The method may be performed by a first communication apparatus, and the method includes: receiving modulation and coding indication information from a second communication apparatus, where the modulation and coding indication information indicates an MCS corresponding to each layer of data in N layers of data to be sent by the second communication apparatus; receiving N bitstreams that are from the second communication apparatus and that are corresponding to the N layers of data; separately demodulating and decoding the N bitstreams based on the MCS corresponding to each layer of data in the N layers of data, to obtain the N layers of data; and reconstructing the N layers of data, to obtain first data.

In the foregoing communication method, the first communication apparatus may be a terminal device, a component (for example, a processor, a chip, or a chip system) of the terminal device, an apparatus that matches the terminal device for use, or the like. The second communication apparatus may be a network device, a component (for example, a processor, a chip, or a chip system) of the network device, an apparatus that matches the network device for use, or the like. Alternatively, the first communication apparatus may be a terminal device, a component of the terminal device, an apparatus that matches the terminal device for use, or the like, and the second communication apparatus is a terminal device different from the first communication apparatus, a component of the terminal device, or an apparatus that matches the terminal device for use.

In a possible design, the method further includes: receiving resource configuration information from the second communication apparatus, where the resource configuration information is used to configure M transport blocks TBs for transmitting the N layers of data, and M is an integer greater than or equal to 1; and the receiving N bitstreams that are from the second communication apparatus and that are corresponding to the N layers of data includes: receiving the N bitstreams from the second communication apparatus on the M TBs.

In a possible design, MCSs corresponding to any two layers of data in the N layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

According to a fourth aspect, an embodiment of this application provides a communication method. The method may be performed by a second communication apparatus, and the method includes: performing layering on first data, to obtain N layers of data, where N is an integer greater than or equal to 2; obtaining a source contribution degree of each layer of data in the N layers of data, where the source contribution degree of each layer of data in the N layers of data indicates a deviation caused to the first data when the layer of data is missing; sending modulation and coding indication information to a first communication apparatus, where the modulation and coding indication information indicates an MCS corresponding to each layer of data in the N layers of data, and the MCS corresponding to each layer of data in the N layers of data is determined based on a ranking, in the N layers of data, of the source contribution degree of each layer of data in the N layers of data and a policy of mapping between a source contribution degree ranking and an MCS; separately performing coding and modulation on the N layers of data based on the MCS corresponding to each layer of data in the N layers of data, to obtain N bitstreams; and sending the N bitstreams to the first communication apparatus.

In a possible design, the performing layering on first data, to obtain N layers of data includes: determining, based on a first data type of the first data and an association relationship between a data type and a layering mode, a first layering mode associated with the first data type; and performing layering on the first data in the first layering mode, to obtain the N layers of data.

In a possible design, the deviation caused to the first data when each layer of data in the N layers of data is missing includes: one or more of a mean square error, a normalized mean square error, an imaging error, a positioning error, and an inference error caused to the first data when each layer of data in the N layers of data is missing.

In a possible design, the method further includes: determining, based on data length information of each layer of data in the N layers of data and the MCS corresponding to each layer of data in the N layers of data, sizes of the N bitstreams corresponding to the N layers of data; determining, based on the sizes of the N bitstreams corresponding to the N layers of data and a quantity O of transport streams for transmitting the N layers of data, M TBs for transmitting the N layers of data, where M and O are integers greater than or equal to 1; and sending resource configuration information to the first communication apparatus, where the resource configuration information is used to configure the M TBs; and the sending the N bitstreams to the first communication apparatus includes: sending the N bitstreams to the second communication apparatus on the M TBs.

In a possible design, when the quantity O of transport streams for transmitting the N layers of data is greater than or equal to 2, the sending the N bitstreams to the first communication apparatus on the M TBs includes: dividing the N bitstreams into O groups of bitstreams based on the sizes of the N bitstreams, where a difference between data volumes of the O groups of bitstreams is minimized; and respectively sending the O groups of bitstreams to the first communication apparatus on the M TBs through the O transport streams.

In a possible design, determining, based on the ranking, in the N layers of data, of the source contribution degree of each layer of data in the N layers of data and the policy of mapping between a source contribution degree ranking and an MCS, the MCS corresponding to each layer of data in the N layers of data includes: determining, based on channel state information with the first communication apparatus, the ranking, in the N layers of data, of the source contribution degree of each layer of data in the N layers of data, and a policy of mapping between an MCS and both channel state information and a source contribution degree ranking, the MCS corresponding to each layer of data in the N layers of data.

In a possible design, MCSs corresponding to any two layers of data in the N layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

According to a fifth aspect, an embodiment of this application provides a communication apparatus. The apparatus has a function of implementing the method in the first aspect or the third aspect. The function may be implemented by using hardware, or may be implemented by using hardware executing corresponding software. The hardware or software includes one or more modules corresponding to the function, for example, includes an interface unit and a processing unit.

In a possible design, the apparatus may be a chip or an integrated circuit.

In a possible design, the apparatus includes a memory and a processor. The memory is configured to store instructions executed by the processor. When the instructions are executed by the processor, the apparatus may perform the method in the first aspect or the third aspect.

In a possible design, the apparatus may be an entire terminal device.

According to a sixth aspect, an embodiment of this application provides a communication apparatus. The apparatus has a function of implementing the method in the second aspect or the fourth aspect. The function may be implemented by using hardware, or may be implemented by using hardware executing corresponding software. The hardware or software includes one or more modules corresponding to the function, for example, includes an interface unit and a processing unit.

In a possible design, the apparatus may be a chip or an integrated circuit.

In a possible design, the apparatus includes a memory and a processor. The memory is configured to store instructions executed by the processor. When the instructions are executed by the processor, the apparatus may perform the method in the second aspect or the fourth aspect.

In a possible design, the apparatus may be an entire network device or an entire terminal device.

According to a seventh aspect, an embodiment of this application provides a communication apparatus. The communication apparatus includes an interface circuit and a processor, and the processor and the interface circuit are coupled to each other. The processor is configured to implement the method in the first aspect or the third aspect by using a logic circuit or executing instructions. The interface circuit is configured to: receive a signal from a communication apparatus other than the communication apparatus and transmit the signal to the processor, or send a signal from the processor to a communication apparatus other than the communication apparatus. It may be understood that the interface circuit may be a transceiver or an input/output interface.

Optionally, the communication apparatus may further include a memory, configured to: store instructions executed by the processor, or store input data required for running instructions by the processor, or store data generated after the processor runs instructions. The memory may be a physically independent unit, or may be coupled to the processor, or the processor includes the memory.

According to an eighth aspect, an embodiment of this application provides a communication apparatus. The communication apparatus includes an interface circuit and a processor, and the processor and the interface circuit are coupled to each other. The processor is configured to implement the method in the second aspect or the fourth aspect by using a logic circuit or executing instructions. The interface circuit is configured to: receive a signal from a communication apparatus other than the communication apparatus and transmit the signal to the processor, or send a signal from the processor to a communication apparatus other than the communication apparatus. It may be understood that the interface circuit may be a transceiver or an input/output interface.

Optionally, the communication apparatus may further include a memory, configured to: store instructions executed by the processor, or store input data required for running instructions by the processor, or store data generated after the processor runs instructions. The memory may be a physically independent unit, or may be coupled to the processor, or the processor includes the memory.

According to a ninth aspect, an embodiment of this application provides a communication system. The communication system includes a first communication apparatus and a second communication apparatus. The first communication apparatus may implement the method in the first aspect, and the second communication apparatus may implement the method in the second aspect. Alternatively, the first communication apparatus may implement the method in the third aspect, and the second communication apparatus may implement the method in the fourth aspect.

According to a tenth aspect, an embodiment of this application provides a computer-readable storage medium. The storage medium stores a computer program or instructions. When the computer program or the instructions are executed by a processor, the method in the first aspect, the second aspect, the third aspect, or the fourth aspect can be implemented.

According to an eleventh aspect, an embodiment of this application further provides a computer program product, including a computer program or instructions. When the computer program or the instructions are executed by a processor, the method in the first aspect, the second aspect, the third aspect, or the fourth aspect can be implemented.

According to a twelfth aspect, an embodiment of this application further provides a chip system. The chip system includes a processor and a memory. The processor is coupled to the memory. The memory is configured to store a program or instructions. When the program or the instructions are executed by the processor, the method in the first aspect, the second aspect, the third aspect, or the fourth aspect can be implemented.

For technical effects that can be achieved in the second aspect to the twelfth aspect, refer to the technical effects that can be achieved in the first aspect. Details are not described herein again.

### BRIEF DESCRIPTION OF DRAWINGS

FIG. 1 is a diagram of an architecture of a communication system according to an embodiment of this application;

FIG. 2 is a diagram 1 of a communication method according to an embodiment of this application;

FIG. 3 is a diagram of a layering mode according to an embodiment of this application;

FIG. 4 is a diagram of source characteristic information according to an embodiment of this application;

FIG. 5 is a diagram of code block division according to an embodiment of this application;

FIG. 6 is a diagram of a transport block combination according to an embodiment of this application;

FIG. 7 is a diagram 2 of a communication method according to an embodiment of this application;

FIG. 8 is a diagram 1 of a structure of a communication apparatus according to an embodiment of this application; and

FIG. 9 is a diagram 2 of a structure of a communication apparatus according to an embodiment of this application.

### DESCRIPTION OF EMBODIMENTS

Technical solutions in embodiments of this application may be applied to various communication systems, for example, a global system for mobile communications (global system for mobile communications, GSM), a code division multiple access (code division multiple access, CDMA) system, a wideband code division multiple access (wideband code division multiple access, WCDMA) system, a general packet radio service (general packet radio service, GPRS), a long term evolution (long term evolution, LTE) system, an LTE frequency division duplex (frequency division duplex, FDD) system, an LTE time division duplex (time division duplex, TDD) system, a universal mobile telecommunications system (universal mobile telecommunications system, UMTS), a worldwide interoperability for microwave access (worldwide interoperability for microwave access, WiMAX) communication system, a 5th generation (5th generation, 5G) mobile communication system, or a new radio (new radio, NR) system. The technical solutions provided in this application may be further applied to a future communication system, for example, a 6th generation mobile communication system. The communication system may alternatively be a public land mobile network (public land mobile network, PLMN), a device-to-device (device-to-device, D2D) network, a Wi-Fi network, a machine-to-machine (machine-to-machine, M2M) network, an IoT network, or another network.

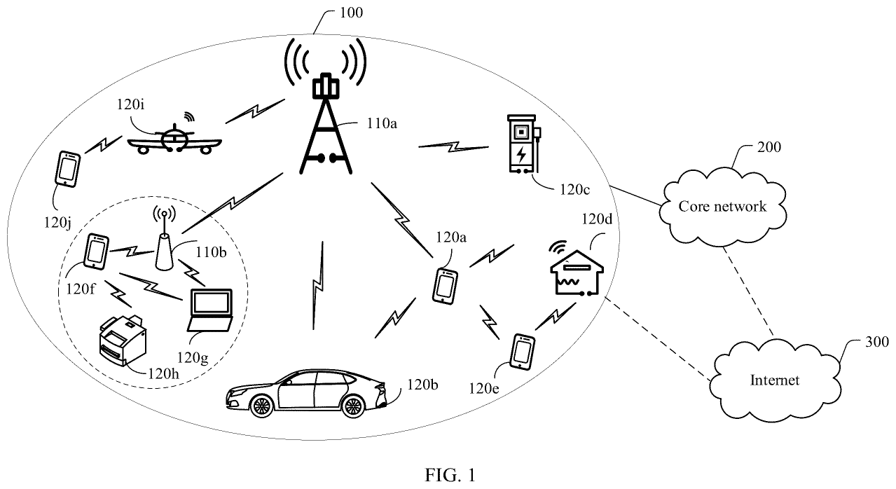

An architecture of the communication system to which embodiments of this application are applied may be shown in FIG. 1. The communication system includes a radio access network 100 and a core network 200. Optionally, the communication system may further include the internet 300. The radio access network 100 may include at least one network device, for example, 110a and 110b in FIG. 1, and may further include at least one terminal device, for example, 120a to 120j in FIG. 1. 110a is a base station, 110b is a micro base station, 120a, 120e, 120f, and 120j are mobile phones, 120b is a vehicle, 120c is a fuel dispenser, 120d is a home access point (home access point, HAP) deployed indoors or outdoors, 120g is a notebook computer, 120h is a printer, and 120i is an uncrewed aerial vehicle. A same terminal device or network device may provide different functions in different application scenarios. For example, mobile phones in FIG. 1 include 120a, 120e, 120f, and 120j. The mobile phone 120a may access the base station 110a, connect to the vehicle 120b, directly communicate with the mobile phone 120e, and access the HAP. The mobile phone 120b may access the HAP and directly communicate with the mobile phone 120a. The mobile phone 120f may access the micro base station 110b, connect to the notebook computer 120g, and connect to the printer 120h. The mobile phone 120j may control the uncrewed aerial vehicle 120i.

The terminal device is connected to the network device, and the network device is connected to the core network. A core network device and the network device may be different physical devices independent of each other; functions of the core network device and logical functions of the network device may be integrated into a same physical device; or some functions of the core network device and some functions of the network device may be integrated into one physical device. Terminal devices may be connected to each other and network devices may be connected to each other in a wired or wireless manner. FIG. 1 is merely a diagram. The communication system may alternatively include another device, for example, may alternatively include a wireless relay device and a wireless backhaul device, which are not shown in FIG. 1.

The network device may also be referred to as a radio access network device, and may be a base station (base station), an evolved NodeB (evolved NodeB, eNodeB), a transmission reception point (transmission reception point, TRP), a next generation NodeB (next generation NodeB, gNB) in a 5th generation (5th generation, 5G) mobile communication system, a base station in a future mobile communication system, an access node in a Wi-Fi system, or the like, or may be a module or unit that completes some functions of the base station, for example, may be a central unit (central unit, CU), or may be a distributed unit (distributed unit, DU). The CU completes functions of a radio resource control protocol and a packet data convergence protocol (packet data convergence protocol, PDCP) of the base station, and may further complete a function of a service data adaptation protocol (service data adaptation protocol, SDAP). The DU completes functions of a radio link control layer and a medium access control (medium access control, MAC) layer of the base station, and may further complete a function of a part or all of a physical layer. For specific descriptions of the foregoing protocol layers, refer to related technical specifications of the 3rd generation partnership project (3rd generation partnership project, 3GPP). The network device may be a macro base station (for example, 110a in FIG. 1), may be a micro base station or an indoor base station (for example, 110b in FIG. 1), or may be a relay node, a donor node, or the like. Neither of a specific technology and a specific device form used by the network device is limited in embodiments of this application.

The terminal device may also be referred to as a terminal, user equipment (user equipment, UE), a mobile station, a mobile terminal, or the like. The terminal device may be widely used in various scenarios, for example, D2D, vehicle-to-everything (vehicle-to-everything, V2X) communication, machine-type communication (machine-type communication, MTC), internet of things (internet of things, IoT), virtual reality, augmented reality, industrial control, autonomous driving, telemedicine, smart grid, smart furniture, smart office, smart wearable, smart transportation, and smart city. The terminal device may be a mobile phone, a tablet computer, a computer with wireless sending and receiving functions, a wearable device, a vehicle, an uncrewed aerial vehicle, a helicopter, an airplane, a ship, a robot, a robot arm, a smart home device, or the like. Neither of a specific technology and a specific device form used by the terminal device is limited in embodiments of this application.

The network device and the terminal device may be at fixed locations, or may be movable. The network device and the terminal device may be deployed on land, including an indoor or outdoor device, a handheld device, or a vehicle-mounted device; or may be deployed on a water surface; or may be deployed on a plane, a balloon, or an artificial satellite in the air. Application scenarios of the network device and the terminal device are not limited in embodiments of this application.

Roles of the network device and the terminal device may be relative. For example, the helicopter or uncrewed aerial vehicle 120i in FIG. 1 may be configured as a mobile network device. For the terminal device 120j that accesses the radio access network 100 via 120i, the terminal device 120i is a network device. However, for the network device 110a, 120i is a terminal device, that is, 110a and 120i communicate with each other by using a radio air interface protocol. Certainly, 110a and 120i may alternatively communicate with each other by using an interface protocol between network devices. In this case, compared with 110a, 120i is also a network device. Therefore, both the network device and the terminal device may be collectively referred to as communication apparatuses. 110a and 110b in FIG. 1 may be referred to as communication apparatuses having a function of a network device, and 120a to 120j in FIG. 1 may be referred to as communication apparatuses having a function of a terminal device.

Communication may be performed between a network device and a terminal device, between network devices, or between terminal devices by using a licensed spectrum, an unlicensed spectrum, or both a licensed spectrum and an unlicensed spectrum; may be performed by using a spectrum below 6 gigahertz (gigahertz, GHz); may be performed by using a spectrum above 6 GHz; or may be performed by using both a spectrum below 6 GHz and a spectrum above 6 GHz. A spectrum resource for wireless communication is not limited in embodiments of this application.

In embodiments of this application, the function of the network device may alternatively be performed by a module (for example, a chip) in the network device, or may be performed by a control subsystem including the function of the network device. The control subsystem including the function of the network device herein may be a control center in the foregoing application scenarios such as smart grid, industrial control, smart transportation, and smart city. The function of the terminal device may alternatively be performed by a module (for example, a chip or a modem) in the terminal device, or may be performed by an apparatus including the function of the terminal device.

Currently, environment sensing, imaging, AI/ML computing, and the like at a physical layer have become potential technologies and new application scenarios in a communication system. In the future, devices such as mobile terminals, sensors, and base stations have capabilities for performing environment sensing and imaging by using electromagnetic signals, to perform offline or real-time modeling and analysis on a wireless transmission environment based on AI/ML or the like. Eventually, performance of the communication system is significantly improved. Because a computing capability and a battery capacity of a single device and an environment range that can be sensed by the single device are limited, a result of sensing, imaging, or AI/ML computing needs to be sent to a remote central node (which may be a base station, a server, a cloud computing center, a terminal device with strong computing power, or the like) in a backhaul manner for information fusion. To meet a transmission requirement of a large amount of data in sensing, imaging, AI/ML, or the like, a UEP solution may be used. Different MCSs are configured for different MIMO streams, to adapt to transmission quality requirements of the different MIMO streams. For example, sensing data of a type 1 and sensing data of a type 2 are respectively transmitted through a MIMO stream 1 and a MIMO stream 2. MCSs may be configured for the MIMO stream 1 and the MIMO stream 2 based on transmission quality requirements of the sensing data of the type 1 and the sensing data of the type 2, to adapt to the transmission quality requirements of the different MIMO streams. However, in this solution, only a transmission quality requirement per stream is considered, and a transmission quality requirement of data is not considered, resulting in low flexibility and inapplicability to a non-MIMO scenario.

In view of this, this application provides a communication method and apparatus, to improve data transmission flexibility and transmission performance by performing UEP layered transmission on to-be-transmitted data, and support UEP data transmission in a non-MIMO scenario. The following describes embodiments of this application in detail with reference to the accompanying drawings.

In addition, it should be understood that ordinal numbers such as “first” and “second” mentioned in embodiments of this application are used to distinguish between a plurality of objects, and are not used to limit sizes, content, a sequence, a time sequence, priorities, importance degrees, or the like of the plurality of objects. For example, a first communication apparatus and a second communication apparatus do not mean different priorities, importance degrees, or the like corresponding to the two communication apparatuses.

In embodiments of this application, unless otherwise specified, a quantity of nouns represents “a singular noun or a plural noun”, that is, “one or more”. “At least one” means one or more, and “a plurality of” means two or more. The term “and/or” describes an association relationship of associated objects, and indicates that three relationships may exist. For example, A and/or B may indicate the following three cases: Only A exists, both A and B exist, and only B exists. A and B may be singular or plural. The character “/” usually indicates an “or” relationship between the associated objects. For example, A/B indicates A or B. “At least one of the following items (pieces)” or a similar expression thereof means any combination of these items, including a single item (piece) or any combination of a plurality of items (pieces). For example, at least one (piece) of a, b, or c represents a, b, c, a and b, a and c, b and c, or a, b, and c, where a, b, and c may be singular or plural.

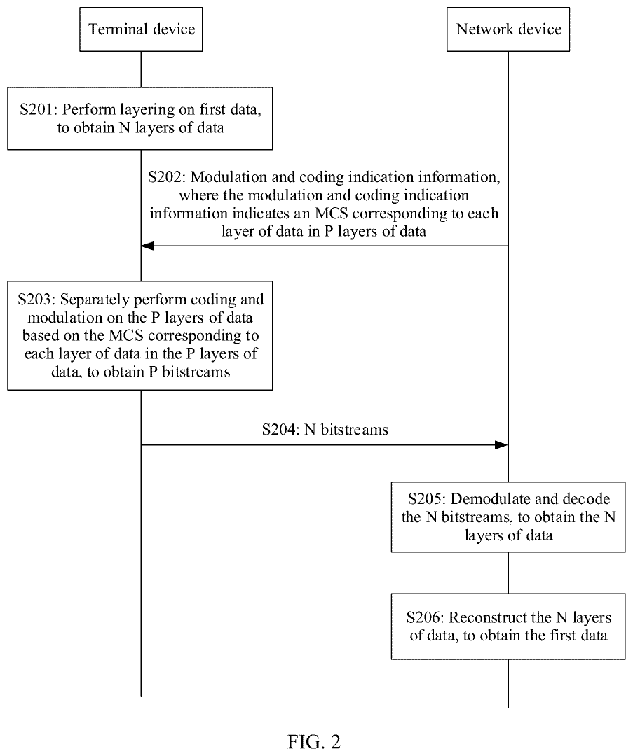

FIG. 2 is a diagram of a communication method according to an embodiment of this application. In FIG. 2, an example in which the method is performed by a network device and a terminal device is used for illustrating the method. However, an execution body of the method is not limited in this application. For example, the network device in FIG. 2 may alternatively be a second communication apparatus, and the second communication apparatus may be a network device, a component (for example, a processor, a chip, or a chip system) of the network device, or an apparatus that matches the network device for use. The terminal device in FIG. 2 may alternatively be a first communication apparatus, and the first communication apparatus may be a terminal device, a component (for example, a processor, a chip, or a chip system) of the terminal device, or an apparatus that matches the terminal device for use. The method includes the following steps.

S201: The terminal device performs layering on first data, to obtain N layers of data, where N is an integer greater than or equal to 2.

In a possible implementation, the terminal device may perform layering on the first data based on a required UEP layer quantity N and a data volume in a manner like average division or random division, to obtain the N layers of data, that is, obtain N pieces of layered data. Optionally, to further reduce a data transmission volume and improve transmission performance, the terminal device may further separately compress the obtained N layers of data.

The required UEP layer quantity N may be predefined in a protocol or preconfigured by the network device for the terminal device, or may be determined by the terminal device based on a UEP requirement for transmitting the first data by the terminal device, or may be determined by the network device based on a UEP requirement for transmitting the first data by the terminal device, and indicated to the terminal device by using layer quantity indication information. This is not limited in this application.

For example, the required UEP layer quantity N is determined by the terminal device based on the UEP requirement for transmitting the first data by the terminal device. Refer to Table 1. A correspondence between a data volume (X) and a UEP requirement (that is, a UEP layer quantity) shown in Table 1 may be preconfigured in the terminal device. When the data volume of the first data is greater than or equal to a data volume threshold 1 and less than a data volume threshold 2, a corresponding UEP layer quantity is 2; when the data volume of the first data is greater than or equal to the data volume threshold 2 and less than a data volume threshold 3, a corresponding UEP layer quantity is 3; when the data volume of the first data is greater than or equal to the data volume threshold 3 and less than a data volume threshold 4, a corresponding UEP layer quantity is 4; . . . ; or when the data volume of the first data is greater than or equal to a data volume threshold Z−1 and less than a data volume threshold Z, a corresponding UEP layer quantity is Z. Z is a maximum available UEP layer quantity, that is, a maximum available value of N. When the data volume of the first data is less than the data volume threshold 1, rollback to a non-layering mode may be performed, that is, the terminal device does not perform UEP layered transmission on the first data.

TABLE 1

| | UEP |
|---|---|
| | requirement |
| | (UEP layer |
| Data volume (X) | quantity) |
| Data volume threshold 1 ≤ X < Data volume threshold 2 | 2 |
| Data volume threshold 2 ≤ X < Data volume threshold 3 | 3 |
| Data volume threshold 3 ≤ X < Data volume threshold 4 | 4 |
| . . . | . . . |
| Data volume threshold Z − 1 ≤ X < Data volume | Z |
| threshold Z | |

In another possible implementation, the terminal device may further store an association relationship between a data type and a layering mode. When performing layering on the first data, the terminal device may further determine, based on a first data type of the first data, a first layering mode associated with the first data type, and perform layering on the first data in the first layering mode associated with the first data type, to obtain the N layers of data.

The network device may indicate or configure, to or for the terminal device by using radio resource control (radio resource control, RRC) signaling or the like sent to the terminal device, the data type of the first data to be transmitted by the terminal device. An information element (information element, IE) of a physical layer data type (PHYData-DataType) field may be set in the RRC signaling or the like, to indicate different data types. Data types that can be indicated by the PHYData-DataType field include but are not limited to the following types:
(1) Sensing signal (SensingSignal): An original sensing signal may be in a form of a real number or complex number signal.
(2) Imaging signal (ImagingSignal): is data obtained by performing imaging on an original sensing signal.
(3) 3D dense point cloud signal (DensePointCloudSignal): is a complete point cloud signal, and has a value at each spatial location.
(4) 3D sparse point cloud signal (SparsePointCloudSignal): is some signal points with high strength obtained through a sparsification operation based on a dense point cloud signal.
(5) AI/ML signal (AIMLSignal): is a signal sent during inference or training in AI/ML.

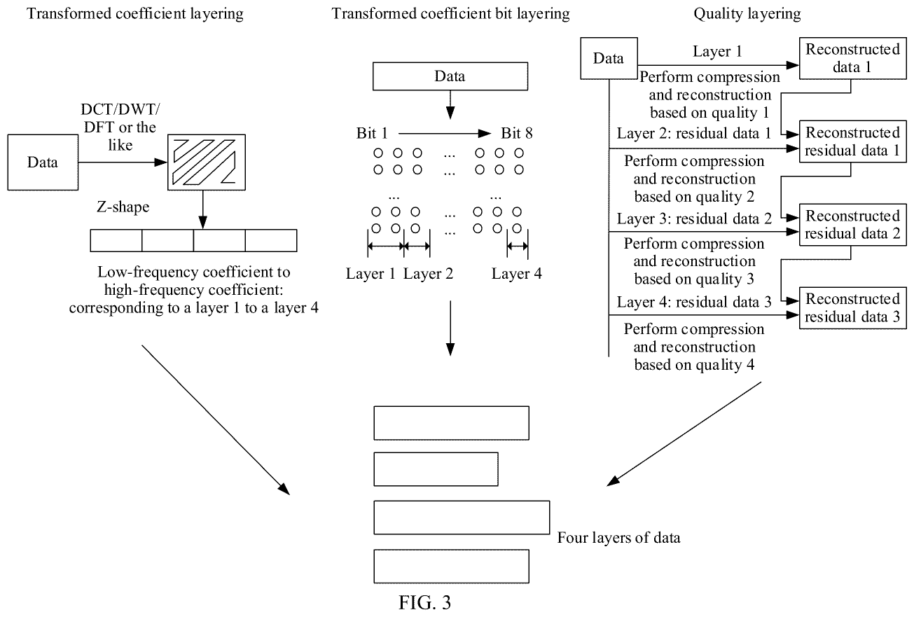

In addition to a layering mode such as average division or random division based on a data volume, the layering mode that can be used in embodiments of this application may alternatively be a mode such as transformed coefficient layering (which may also be referred to as transformed coefficient grouping), quantized coefficient bit layering (which may also be referred to as quantized coefficient bit grouping), or quality layering. Refer to a diagram of a layering mode shown in FIG. 3. When the transformed coefficient layering is used, one or more of discrete cosine transform (discrete cosine transform, DCT), discrete wavelet transform (discrete wavelet transform, DWT), discrete Fourier transform (discrete Fourier transform, DFT), and the like may be first performed on data, and layering is performed on transformed data based on a low-frequency coefficient to a high-frequency coefficient or in another manner (in FIG. 3, division into four layers is used as an example). When the quantized coefficient bit layering is used, layering may be performed based on a quantized coefficient. For example, quantized coefficients of a plurality of columns are divided into a specified quantity of layers based on a most significant bit and a least significant bit (in FIG. 3, division into four layers is used as an example). When the quality layering is used, original data (for example, the first data) may be first compressed and reconstructed based on low quality 1 to obtain reconstructed data 1, and then residual data 1 is obtained by calculating a residual between the original data and the reconstructed data 1. The residual data 1 is compressed and reconstructed based on quality 2 to obtain reconstructed residual data 1. Herein, the quality 2 is better than the quality 1 (for example, a quantized coefficient of the quality 2 is less than a quantized coefficient of the quality 1 through adjustment based on a quantized coefficient in a compression parameter). Then, residual data 2 is obtained by calculating a residual between the residual data 1 and the reconstructed residual data 1, and the residual data 2 is compressed and reconstructed based on quality 3 to obtain reconstructed residual data 2. Herein, the quality 3 is better than the quality 2. Finally, residual data 3 is obtained by calculating a residual between the residual data 2 and the reconstructed residual data 2, and the residual data 3 is compressed based on quality 4 to obtain reconstructed residual data 3. Herein, the quality 4 is better than the quality 3. A total of four layers of data corresponding to the reconstructed data 1, the reconstructed residual data 1, the reconstructed residual data 2, and the reconstructed residual data 3 may be obtained through the foregoing operations. The four layers of data also respectively correspond to the original data and three pieces of residual data (the residual data 1 to the residual data 3).

For example, a layering mode associated with the sensing signal may be transformed coefficient layering, quantized coefficient bit layering, or the like. When the data type of the first data is the sensing signal, the terminal device may perform preprocessing such as Fourier transform or spatial transform on the first data (that is, the sensing signal), then perform discrete cosine transform, wavelet transform, or the like, quantize a transformed coefficient, and finally perform layering based on a quantized coefficient. For example, layering is performed based on high-frequency and low-frequency coefficients to implement transformed coefficient layering on the first data, or layering is performed based on a most significant bit and a least significant bit to implement quantized coefficient bit layering on the first data.

A layering mode associated with the imaging signal may be transformed coefficient layering, quantized coefficient bit layering, or the like. When the data type of the first data is the imaging signal, the terminal device may perform discrete cosine transform, wavelet transform, or the like on the first data (that is, the imaging signal), quantize a transformed coefficient, and finally perform a layering operation based on a quantized coefficient. For example, layering is performed based on high-frequency and low-frequency coefficients to implement transformed coefficient layering on the first data, or layering is performed based on a most significant bit and a least significant bit to implement quantized coefficient bit layering on the first data.

A layering mode associated with the 3D dense point cloud signal may be quality layering or the like. When the data type of the first data is the 3D dense point cloud signal, three dimensions are a length, a width, and a height respectively, and the terminal device may separately compress two-dimensional data (corresponding to the length and the width) of the first data (that is, the 3D dense point cloud signal) at each height, complete a layering operation (for example, quality layering) in a compression process, and introduce predictive coding to two-dimensional data at an adjacent height, for example, perform a differential coding operation, to reduce data redundancy to some extent.

A layering mode associated with the 3D sparse point cloud signal may be quantized coefficient bit layering, quality layering, or the like. When the data type of the first data is the 3D sparse point cloud signal, the terminal device may perform compression in a manner of quantization or entropy encoding by using quadtree transform, octree transform, or the like, and introduce a layering operation during quantization, for example, quantized coefficient bit layering or quality layering.

A layering mode associated with the AI/ML signal may be quantized coefficient bit layering, quality layering, or the like. When the data type of the first data is the AI/ML signal, the terminal device may perform compression in a manner like quantization or entropy encoding by using a predefined codebook, and introduce a layering operation during quantization, for example, quantized coefficient bit layering or quality layering.

It should be understood that, in addition to determining, based on the association relationship between a data type and a layering mode, the first layering mode used to perform layering on the first data, the terminal device may alternatively determine, based on an indication of the network device, the first layering mode used to perform layering on the first data. For example, the network device may indicate, by using RRC signaling or the like sent to the terminal device, the first layering mode used to perform layering on the first data. In the RRC signaling or the like, a layering mode (LayerMode) field may be set to indicate the first layering mode used to perform layering on the first data. In addition, it may be understood that, when the UEP layer quantity N is configured or indicated by the network device, in the RRC signaling or the like sent by the network device to the terminal device, a layer quantity (LayerNum) field may be further set to indicate the UEP layer quantity N.

S202: The network device sends modulation and coding indication information to the terminal device, where the modulation and coding indication information indicates an MCS corresponding to each layer of data in P layers of data. Correspondingly, the terminal device receives the modulation and coding indication information. The MCS corresponding to each layer of data in the P layers of data is determined based on a ranking of a source contribution degree of the layer of data in the P layers of data and a policy of mapping between a source contribution degree ranking and an MCS.

The P layers of data belong to the N layers of data, the source contribution degree of each layer of data in the P layers of data indicates a deviation caused to the first data when the layer of data is missing, and P is less than or equal to N.

In embodiments of this application, for the source contribution degree of each layer of data in the P layers of data, after determining a source contribution degree of each layer of data in the N layers of data in the first data, the terminal device may send source contribution degrees of the P layers of data to the network device by using source characteristic information or the like. The terminal device may determine the source contribution degree of each layer of data in the N layers of data based on a deviation caused to the first data when the layer of data is missing. For example, for the source contribution degree of each layer of data in the N layers of data, the terminal device may use, as the source contribution degree of the layer of data, a deviation such as a mean square error (mean square error, MSE) or a normalized mean square error (normalized mean square error, NMSE) of the first data in which the layer of data is missing relative to the complete first data.

In an example, the first data is denoted as Y, and reconstructed data obtained due to missing of an n^{th} layer of data is denoted as Y′ₙ. In this case, it may be learned that a mean square error corresponding to the n^{th} layer of data is

$${MSE}_{n} = \frac{1}{L} {\sum }_{i = 1}^{L} {( Y ( i ) - {Y}_{n}^{′} ( i ) )}^{2} ,$$

where L represents a length of the first data (for example, a quantity of bits or a quantity of coefficients in the data).

In some implementations, the terminal device may alternatively use a corresponding source contribution degree determining manner based on the data type of the first data, to more truly reflect an importance degree of each layer of data in the first data. For example, when the data type of the first data is the sensing signal, the source contribution degree of each layer of data may be determined based on a deviation such as a mean square error or a normalized mean square error caused to the first data when the layer of data is missing. When the data type of the first data is the imaging signal, the source contribution degree of each layer of data may be determined based on a deviation such as a mean square error or a normalized mean square error caused to the first data when the layer of data is missing, and may also be determined based on an imaging error caused to the first data when the layer of data is missing. When the data type of the first data is the 3D dense point cloud signal, the source contribution degree of each layer of data may be determined based on a deviation such as a mean square error or a normalized mean square error caused to the first data when the layer of data is missing, and may also be determined based on a geometric feature deviation such as a chamfer distance error caused to the first data when the layer of data is missing. When the data type of the first data is the 3D sparse point cloud signal, the source contribution degree of each layer of data may be determined based on a deviation such as a mean square error or a normalized mean square error caused to the first data when the layer of data is missing, and may also be determined based on a positioning error caused to the first data when the layer of data is missing. When the data type of the first data is the AI/ML signal, the source contribution degree of each layer of data may be determined based on a deviation such as a mean square error or a normalized mean square error caused to the first data when the layer of data is missing, and may also be determined based on an inference error (an inference error of an AI/ML model corresponding to the AI/ML signal) caused to the first data when the layer of data is missing.

In some implementations, the source contribution degree determining manner may be alternatively indicated or configured by the network device by sending RRC signaling or the like to the terminal device. For example, in the RRC signaling or the like, a layer importance (LayerImportance) field may be set to indicate the source contribution degree determining manner. For example, a mean square error is used.

After determining the source contribution degree of each layer of data in the N layers of data in the first data, the terminal device may send the source contribution degree of each layer of data in the P layers of data to the network device by using the source characteristic information.

In a possible implementation, P may be equal to N, that is, the source characteristic information sent by the terminal device to the network device may include the source contribution degree of each layer of data in the N layers of data.

In another possible implementation, P may alternatively be less than N, that is, the source characteristic information sent by the terminal device to the network device may include source contribution degrees of some layers of data in the N layers of data. In an example, the terminal device may store a source contribution degree threshold predefined in a protocol or preconfigured by the network device. For the N layers of data, the terminal device sends, to the network device by using the source characteristic information, only a source contribution degree of each layer of data in P layers of data whose corresponding source contribution degrees are greater than the source contribution degree threshold in the N layers of data. Alternatively, the terminal device may store a reporting proportion S predefined in a protocol or preconfigured by the network device. For the N layers of data, the terminal device may send, to the network device by using the source characteristic information, only a source contribution degree of each layer of data in P (P=N*S) layers of data with higher source contribution degrees in the N layers of data.

It should be understood that the source contribution degree that is of each layer of data in the P layers of data and that is sent by the terminal device to the network device may be an unquantized original source contribution degree of each layer of data in the P layers of data, or may be a quantized source contribution degree of each layer of data in the P layers of data (for example, a source contribution degree quantized to an interval of 1 to 10, or a source contribution degree calculated through rounding), or may be a ranking, in the P layers of data, of the source contribution degree of each layer of data in the P layers of data (for example, a ranking, in the P layers of data, of the source contribution degree of each layer of data in the P layers of data determined in descending order of source contribution degrees of the P layers of data).

In addition, to help the network device accurately restore the N layers of data from a bitstream from the terminal device subsequently, in addition to the source contribution degree (C) of each layer of data in the P layers of data in the N layers of data, the source characteristic information sent by the terminal device to the network device may further include data length information (L) of each layer of data in the N layers of data.

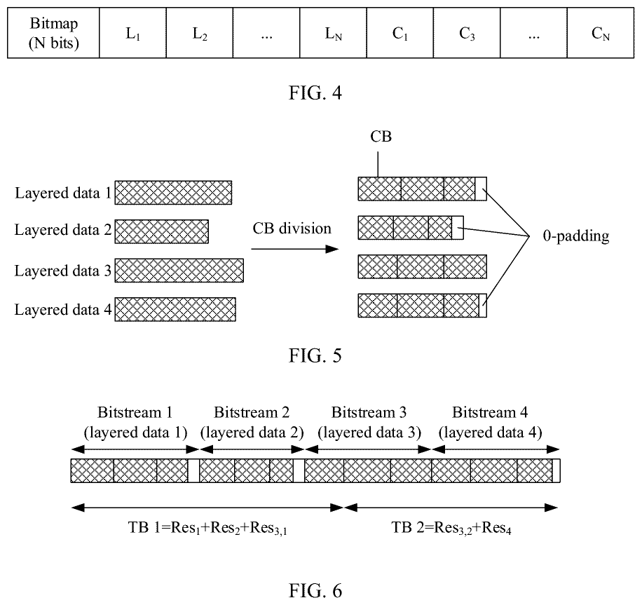

For example, refer to a diagram of source characteristic information shown in FIG. 4. The source characteristic information may include N+P+1 parameters, where a parameter bitmap (bitmap) includes N bits (bits) for indicating P layers of data whose source contribution degrees are sent in N layers of data. A bitmap 1011 . . . 1 indicates that the source characteristic information includes source contribution degrees of a total of P layers of data: a 1^{st} layer of data (that is, a 1^{st} piece of layered data), a 3^{rd} layer of data (that is, a 3^{rd} piece of layered data), a 4^{th} layer of data (that is, a 4^{th} piece of layered data), . . . , and an N^{th} layer of data (that is, an N^{th} piece of layered data), in N layers of data. N parameters L₁, L₂, . . . , and L_{N} represent data length information (for example, a quantity of bytes or a quantity of code blocks of a specific length (for example, a quantity of 512-bit code blocks)) of the 1^{st}, 2^{nd}, and N^{th} layers of data, and P parameters C₁, C₃, . . . , and C_{N} represent the source contribution degrees of the 1^{st}, 3^{rd}, . . . , and N^{th} layers of data. For a layer for which no source contribution degree is reported, a source contribution degree related to data at the layer is not sent. For example, for the 2^{nd} layer of data, only the data length information (L₂) is reported, and a source contribution degree (C₂) is not reported.

It may be understood that the network device may not only obtain, by using the source characteristic information reported by the terminal device, the source contribution degree of each layer of data in the P layers of data in the first data to be sent by the terminal device. Alternatively, the source contribution degree of each layer of data in the P layers of data in the first data to be sent by the terminal device may be obtained in another manner.

In an example, a plurality of pieces of data sent by the terminal device scheduled by the network device in a period of time by using downlink control information (downlink control information, DCI) or the like are usually of a same type or similar types. For the plurality of pieces of data sent by the terminal device to the network device in the period of time (for example, a reporting period), the terminal device may evenly divide the plurality of pieces of data into layers of a same quantity, and send, to the network device only before a 1^{st} piece of data in the period of time is sent to the network device, a source contribution degree of each layer of data in P layers of data in the data. For subsequent data (for example, the first data) in the period, the network device may continue to use a configuration of the source contribution degree of each layer of data in the previous P layers of data.

Alternatively, if there is another terminal device in a same cell as the terminal device that is to send the first data, the network device may further continue to use a configuration of a source contribution degree of each layer of data in P layers of data reported by the another terminal device as the source contribution degree of each layer of data in the P layers of data of the terminal device.

For determining the MCS corresponding to each layer of data in the P layers of data, in a possible implementation, the network device may maintain one or more tables of mapping between a source contribution degree ranking and an MCS. The terminal device and the network device may negotiate a to-be-used table of mapping between a source contribution degree ranking and an MCS, or the network device determines a to-be-used table of mapping between a source contribution degree ranking and an MCS. After obtaining the source contribution degree of each layer of data in the P layers of data in the first data to be sent by the terminal device, the network device may determine, based on the ranking, in the P layers of data, of the source contribution degree of each layer of data in the P layers of data (for example, in descending order), the MCS corresponding to each layer of data in the P layers of data.

For example, a used table of mapping between a source contribution degree ranking and an MCS is shown in Table 2, and a source contribution degree ranking in each column corresponds to (or is mapped to) an MCS in the column. For example, a ranking 1 corresponds to MCS₁, a ranking 2 corresponds to MCS₂, . . . , and a ranking Z corresponds to MCS_{Z}. A value of Z may be determined based on a maximum available layer quantity supported by the network device and the terminal device. If P is 4, in the four layers of data, layered data whose source contribution degree ranking is 1 corresponds to MCS₁, layered data whose source contribution degree ranking is 2 corresponds to MCS₂, layered data whose source contribution degree ranking is 3 corresponds to MCS₃, and layered data whose source contribution degree ranking is 4 corresponds to MCS₄.

TABLE 2

| 1 | 2 | 3 | . . . | Z |
|---|---|---|---|---|
| MCS₁ | MCS₂ | MCS₃ | . . . | MCS_{Z} |

In another possible implementation, the network device may alternatively maintain one or more tables of mapping between an MCS and both channel state information and a source contribution degree ranking. The terminal device and the network device may negotiate a to-be-used table of mapping between an MCS and both channel state information and a source contribution degree ranking, or the network device determines a to-be-used table of mapping between an MCS and both channel state information and a source contribution degree ranking. After obtaining the source contribution degree of each layer of data in the P layers of data in the first data to be sent by the terminal device, the network device may determine, based on channel state information between the network device and the terminal device and the ranking, in the P layers of data, of the source contribution degree of each layer of data in the P layers of data, the MCS corresponding to each layer of data in the P layers of data. The channel state information may be one or more of a signal-to-noise ratio (signal-to-noise ratio, SNR), reference signal received quality (reference signal received quality, RSRQ), a bit error rate (bit error ratio, BER), and the like.

For example, the channel state information is the SNR. A used table of mapping between an MCS and both channel state information and a source contribution degree ranking is shown in Table 3. One MCS may be uniquely determined based on a column to which a source contribution degree ranking belongs and an SNR interval to which an SNR between the network device and the terminal device belongs. An SNR interval₁, an SNR interval₂, an SNR interval₃, . . . , and an SNR interval_{D} do not overlap. For example, if the SNR between the network device and the terminal device belongs to the SNR interval₁, and a ranking of a source contribution degree of a layer of data in the P layers of data is 1, it may be determined that an MCS corresponding to the layer of data is MCS_{1,1}. If the SNR between the network device and the terminal device belongs to the SNR interval₁, and a ranking of a source contribution degree of a layer of data in the P layers of data is 2, it may be determined that an MCS corresponding to the layer of data is MCS_{1,2}.

TABLE 3

| | | Source contribution degree ranking | | | | |
|---|---|---|---|---|---|---|
| | | 1 | 2 | 3 | . . . | Z |
| Channel | SNR interval₁ | MCS_{1,1} | MCS_{1,2} | MCS_{1,3} | . . . | MCS_{1,Z} |
| state | SNR interval₂ | MCS_{2,1} | MCS_{2,2} | MCS_{2,3} | . . . | MCS_{2,Z} |
| interval | SNR interval₃ | MCS_{3,1} | MCS_{3,2} | MCS_{3,3} | . . . | MCS_{3,Z} |
| | . . . | . . . | . . . | . . . | . . . | . . . |
| | SNR interval_{D} | MCS_{D,1} | MCS_{D,2} | MCS_{D,3} | . . . | MCS_{D,Z} |

Using D=4 and Z=8 as an example, an MCS that is mapped to channel state information and a source contribution degree ranking may be specifically shown in Table 4. Quadrature phase shift keying (quadrature phase shift keying, QPSK) represents a modulation scheme with a modulation order of 4 (that is, a quantity of modulation bits is log 2(4)=2), 16 quadrature amplitude modulation (quadrature amplitude modulation, QAM) represents a modulation scheme with a modulation order of 16 (that is, a quantity of modulation bits is log 2(16)=4), and 32QAM represents a modulation scheme with a modulation order of 32 (that is, a quantity of modulation bits is log 2(32)=5). Refer to Table 4. If the SNR between the network device and the terminal device belongs to the SNR interval₁, and a ranking of a source contribution degree of layered data in the P layers of data is 1, an MCS (that is, MCS_{1,1}) corresponding to the layer of data is a modulation and coding scheme with a code rate (Rate) of ½ and a modulation order of 4; if the SNR between the network device and the terminal device belongs to the SNR interval₁, and a ranking of a source contribution degree of layered data in the P layers of data is 2, an MCS (that is, MCS_{1,2}) corresponding to the layer of data is a modulation and coding scheme with a rate of 17/32 and a modulation order of 4; . . . ; or if the SNR between the network device and the terminal device belongs to the SNR interval₄, and a ranking of a source contribution degree of layered data in the P layers of data is 8, an MCS (that is, MCS_{4,8}) corresponding to the layer of data is a modulation and coding scheme with a rate of 25/32 and a modulation order of 32.

TABLE 4

| | 1 | 2 | 3 | 4 | 5 | 6 | 7 | 8 |
|---|---|---|---|---|---|---|---|---|
| SNR | Rate of | Rate of | Rate of | Rate of | Rate of | Rate of | Rate of | Rate of |
| interval₁ | ½, | 17/32, | 9/16, | 19/32, | ⅝, | 21/32, | 11/16, | 23/32, |
| | QPSK | QPSK | QPSK | QPSK | QPSK | QPSK | QPSK | QPSK |
| SNR | Rate of | Rate of | Rate of | Rate of | Rate of | Rate of | Rate of | Rate of |
| interval₂ | ½, | 17/32, | 9/16, | 19/32, | ⅝, | 21/32, | 11/16, | 23/32, |
| | 16QAM | 16QAM | 16QAM | 16QAM | 16QAM | 16QAM | 16QAM | 16QAM |
| SNR | Rate of | Rate of | Rate of | Rate of | Rate of | Rate of | Rate of | Rate of |
| interval₃ | ½, | 17/32, | 9/16, | 19/32, | ⅝, | 21/32, | 11/16, | 23/32, |
| | 32QAM | 32QAM | 32QAM | 32QAM | 32QAM | 32QAM | 32QAM | 32QAM |
| SNR | Rate of | Rate of | Rate of | Rate of | Rate of | Rate of | Rate of | Rate of |
| interval₄ | ⅞, | ¾, | 25/32, | 13/16, | 27/32, | ⅞, | ¾, | 25/32, |
| | QPSK | 16QAM | 16QAM | 16QAM | 16QAM | 16QAM | 32QAM | 32QAM |

In another possible implementation, the network device may further obtain a corresponding MCS=(Rate, Mod) based on a mapping relationship between channel state information and an MCS and channel state information with the network device, where Mod represents a quantity of modulation bits (that is, a quantity of bits that can be represented by each modulation symbol). For example, quantities of bits that can be represented by each symbol modulation symbol of code types of QPSK, 8QAM, 16QAM, and 32QAM are respectively 2, 3, 4, and 5. Modulation orders corresponding to these code types are respectively 4, 8, 16, and 32. Rate indicates a preset code rate.

Same modulation Mod may be used for all layers of data, that is, a same modulation order is used, and only code rates (Rate) are distinguished.

$${Rate}_{n} = {L}_{n} / ( \frac{{\sum }_{i = 1}^{P} {L}_{i}}{Rate} \times \frac{{C}_{n}^{α}}{{\sum }_{i = 1}^{P} {C}_{i}^{α}} )$$

A code rate of an n^{th} layer of data in the P layers of data is Rateₙ, Cₙ^{α} is a source contribution degree of the n^{th} layer of data in the P layers of data raised to the power of α, Lₙ is a data length of the n^{th} layer of data in the P layers of data, a is an adjustment factor, α>0, and Rate represents a preset code rate. To be specific, a lower code rate is allocated to a data layer with a higher source contribution degree, to perform key protection. A smaller value of a indicates a smaller code rate difference (closer protection degrees) between layers. A candidate value set A={α₁, α₂, . . . , α_{N}} may be first determined for a in advance. The network device may select a value of a from the set A, and may further configure the selected value of a for the terminal device by using RRC signaling, so that the terminal device calculates a code rate of each layer of data.

It should be understood that, in embodiments of this application, determined MCSs corresponding to any two layers of data in the P layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data. In other words, when the foregoing table of mapping between a source contribution degree ranking and an MCS, the foregoing table of mapping between an MCS and both channel state information and a source contribution degree ranking, and the like satisfy a same channel state (or the channel state is not considered), as source contribution degrees of layered data increase in descending order of rankings, modulation orders and/or code rates of corresponding MCSs are in an increasing trend. In this way, a lower code rate and/or modulation order may be used for layered data corresponding to a larger source contribution degree compared with layered data corresponding to a smaller source contribution degree, to obtain stronger transmission robustness and ensure transmission performance.

S203: The terminal device separately performs coding and modulation on the P layers of data based on the MCS corresponding to each layer of data in the P layers of data, to obtain P bitstreams.

S204: The terminal device sends N bitstreams to the network device. Correspondingly, the network device receives the N bitstreams, where the N bitstreams include the P bitstreams and N—P bitstreams corresponding to N—P layers of data other than the P layers of data in the N layers of data.

After determining the MCS corresponding to each layer of data in the P layers of data, the network device may send, to the terminal device, the modulation and coding indication information used to indicate the MCS corresponding to each layer of data in the P layers of data, to indicate, to the terminal device, the MCS used for each layer of data in the P layers of data. After receiving the MCS corresponding to each layer of data in the P layers of data, the terminal device may separately perform coding and modulation on the P layers of data based on the MCS (such as a code rate and a modulation order) corresponding to each layer of data in the P layers of data, to obtain the P bitstreams.

For the N—P layers of data other than the P layers of data in the N layers of data, MCSs used for the N—P layers of data may be preconfigured or agreed on by the network device and the terminal device in a manner such as protocol predefinition or indication by the network device. For example, an MCS used for the N—P layers of data may be preconfigured; or it may be pre-agreed that an MCS corresponding to a 1^{st} layer of data in the P layers of data or an MCS corresponding to a P^{th} layer of data in the P layers of data is used for the N—P layers of data. The terminal device may further separately perform coding and modulation on the N—P layers of data based on the MCSs used for the N—P layers of data, to obtain the N—P bitstreams.

After obtaining a total of N bitstreams including the P bitstreams corresponding to the P layers of data in the N layers of data and the N—P bitstreams corresponding to the N—P layers of data other than the P layers of data in the N layers of data, the terminal device may send the N bitstreams to the network device, for example, send the N bitstreams to the network device on an uplink shared channel. Correspondingly, the network device receives the N bitstreams from the terminal device.

S205: The network device demodulates and decodes the N bitstreams, to obtain the N layers of data.

S206: The network device reconstructs the N layers of data, to obtain the first data.

After receiving the N bitstreams, the network device may demodulate and decode the P bitstreams corresponding to the P layers of data in the N bitstreams based on the MCS corresponding to each layer of data in the P layers of data, to obtain the P layers of data; and may separately demodulate and decode the N—P bitstreams corresponding to the N—P layers of data other than the P layers of data based on the MCSs used for the N—P layers of data, to obtain the N—P layers of data. After obtaining the P layers of data and the N—P layers of data, the network device may reconstruct the N layers of data to obtain the first data. For example, the N layers of data are concatenated based on a location of each layer of data in the N layers of data (or a layer number in the N layers of data), to obtain the first data.

It should be understood that, if the terminal device concatenates the N bitstreams together for sending, the network device may further determine, based on the data length information corresponding to each layer of data in the N layers of data and the corresponding MCS, a bitstream size corresponding to each layer of data, to determine a switching point of each bitstream, so as to demodulate and decode the N bitstreams.

In the foregoing method, the network device may configure a transmission resource (for example, a transport block (transport block, TB)) for the terminal device based on an optional lowest bitstream and lowest modulation order (or a minimum quantity of modulation bits), so that the terminal device has sufficient resources to send the N bitstreams. In some implementations, to improve resource utilization, the network device may further determine, based on the data length information of each layer of data in the N layers of data, the MCS corresponding to each layer of data in the P layers of data in the N layers of data, and the MCSs corresponding to the N—P layers of data, sizes of the N bitstreams corresponding to the N layers of data; and determine, based on the sizes of the N bitstreams and a quantity O of transport streams for transmitting the N layers of data, M TBs for transmitting the N layers of data (that is, the N bitstreams corresponding to the N layers of data), where M and O are integers greater than or equal to 1.

Specifically, after obtaining MCSₙ=(Rateₙ, Modₙ) of each layer, the network device may estimate a quantity of transmission resources (namely, a quantity of symbols) of each layer, where n represents an n^{th} layer of data in the N layers of data, and MCSₙ, Rateₙ, and Mod represent an MCS, a code rate, and a quantity of modulation bits corresponding to the n^{th} layer of data in the N layers of data.

$${Res}_{n} = ⌈ ( {L}_{n} + Δ {L}_{n} ) / ( {Rate}_{n} \times {Mod}_{n} ) ⌉$$

ΔLₙ represents a bit length increase value caused by cyclic redundancy check (cyclic redundancy check, CRC), zero padding, and the like. When a CRC length L_{crc} and a code block (code block, CB) bit size K_{cb,n} (which may be different for each layer) are given, it can be learned through calculation that ΔLₙ=N_{cb}L_{crc}+(N_{cb}K_{cb,n}−Lₙ), where N_{cb} └Lₙ/K_{cb,n}┘, and └⋅┘ represents a rounding up operation. Modₙ may be determined based on a modulation order. For example, modulation orders of QPSK, 8QAM, 16QAM, and 32QAM are respectively 4, 8, 16, and 32, and corresponding quantities of bits that can be represented by each modulation symbol are respectively 2, 3, 4, and 5. A CB size of each layer of data in the N layers of data may be predefined in a protocol or configured by the network device.

A total quantity of transmission resources (that is, a size of the N bitstreams) is Res=Σₙ₌₁^{N} Resₙ. The network device may estimate a required TB symbol length L_{tb} and a required quantity M based on a current available resource quantity Resₐᵥᵢ, that is, a supported maximum TB (the maximum TB may be determined based on a product of a quantity of supported consecutive slots (slot), a quantity of RBs in each slot, a quantity of symbols in each RB, and a quantity of transport layers (layer)).

$${L}_{t b} = min ( Res , {Res}_{avi} ) , M = ⌈ Res / {L}_{t b} ⌉$$

After determining the required M, the network device indicates M to the terminal device by using the resource configuration information. For example, the quantity of the M TBs and a symbol length are indicated to the terminal device.

Using N=4 as an example, in a diagram of CB division shown in FIG. 5, the terminal device may divide each layer of data into one or more CBs based on a size of each layer of CBs, perform a 0-padding (padding) operation on a CB that is not fully padded, perform coding and modulation on a divided CB based on an MCS corresponding to each layer, to obtain a bitstream corresponding to each layer, and then pad, based on the configured M (2 is used as an example) TBs, a coded and modulated bitstream of each layer into the M TBs. After four bitstreams corresponding to four layers of data (layered data 1 to layered data 4) shown in FIG. 5 are padded into two TBs (for example, a TB 1 and a TB 2), a TB combination shown in FIG. 6 may be obtained, where the TB 1 includes a resource (Res₁) of a bitstream 1, a resource (Res₂) of a bitstream 2, and a partial resource (Res_{3,1}) of a bitstream 3, and the TB 2 includes a remaining resource (Res_{3,2}) of the bitstream 3 and a resource (Res₄) of a bitstream 4.

In some implementations, when MIMO transmission is configured for the terminal device and the network device, that is, when the quantity O of transport streams between the terminal device and the network device is greater than or equal to 2, the network device may divide the N bitstreams into O groups of bitstreams based on the sizes of the N bitstreams corresponding to the N layers of data, where a difference between data volumes of the O groups of bitstreams is minimized. For example, all possible grouping manners of dividing the N bitstreams into the O groups of bitstreams are traversed, a grouping manner in which the difference between the data volumes of the O groups of bitstreams is minimum (or may be less than a threshold) is selected, and the M TBs for transmitting the N layers of data are determined based on a data volume of a group of bitstreams corresponding to a largest data volume in the O groups of bitstreams. Similarly, the terminal device may also divide the N bitstreams into the O groups of bitstreams based on the sizes of the N bitstreams corresponding to the N layers of data, where a difference between data volumes of the O groups of bitstreams is minimized; and respectively send the O groups of bitstreams to the network device on the M TBs through the O transport streams.

In the foregoing implementation, for each layer of data in the P layers of data, when the MCS corresponding to the layer of data is determined based on the channel state information between the network device and the terminal device, the ranking of the source contribution degree of the layer of data in the P layers of data, and the policy of mapping between an MCS and both channel state information and a source contribution degree ranking, if channel state information of the O transport streams is different, channel state information (for example, an SNR) of a transport stream may be selected as the channel state information between the network device and the terminal device randomly, according to a specific policy (for example, selecting a maximum value or a minimum value), or in another manner.

In some implementations, if the channel state information of the O transport streams is different, the O groups of bitstreams may be further divided and the MCS of each layer of data may be configured based on channel state information of each transport stream and source contribution degree rankings of the P layers of data.

The following provides descriptions by using an example in which four layers of data (denoted as layered data 1, . . . , and layered data 4 in descending order of source contribution degrees) are obtained through division, there are two transport streams, an SNR of a transport stream 1 (denoted as SNR_{Rx,1}) is greater than a received SNR of a transport stream 2 (denoted as SNR_{Rx,2}), most important layered data is preferentially sent by using a transmission resource of the transport stream 1, and other layered data is sent by using a transmission resource of the transport stream 2.

(1) Resource estimation: According to a table (as shown in Table 3) of mapping between an MCS and both channel state information and a source contribution degree ranking, an MCS group 1 corresponding to the layered data 1 to the layered data 4 is selected based on SNR_{Rx,1} (that is, an MCS group including MCSs respectively corresponding to the layered data 1 to the layered data 4 is determined based on SNR_{Rx,1} with reference to source contribution degree rankings of the layered data 1 to the layered data 4), an MCS group 2 corresponding to the layered data 1 to the layered data 4 is selected based on SNR_{Rx,2} (that is, an MCS group including MCSs respectively corresponding to the layered data 1 to the layered data 4 is determined based on SNR_{Rx,2} with reference to the source contribution degree rankings of the layered data 1 to the layered data 4), and two groups of MCSs are selected in total. Based on the two groups of selected MCSs and data lengths of the layered data 1 to the layered data 4, transmission resource quantities Res_{1,1} to Res_{1,4} respectively corresponding to the layered data 1 to the layered data 4 when the MCS group 1 is applied and transmission resource quantities Res_{2,1} to Res_{2,4} respectively corresponding to the layered data 1 to the layered data 4 when the MCS group 2 is applied are estimated, and are respectively corresponding to the transport stream 1 and the transport stream 2.

(2) Transport stream allocation: There are three allocation manners in total: transport stream 1 (the layered data 1) & transport stream 2 (the layered data 2 to the layered data 4), transport stream 1 (the layered data 1 and the layered data 2) & transport stream 2 (the layered data 3 and the layered data 4), and transport stream 1 (the layered data 1 to the layered data 3) & transport stream 2 (the layered data 4). Transmission resource occupation in the three allocation manners is calculated as follows:

Transport stream 1 (the layered data 1) & transport stream 2 (the layered data 2 to the layered data 4): A resource for the transport stream 1 is Res_{1,1}, a resource for the transport stream 2 is Res_{2,2}+Res_{2,3}+Res_{2,4}, and a resource difference percentage of the two transport streams is Diff₁=|1−Res_{1,1}/(Res_{2,2}+Res_{2,3}+Res_{2,4})|.

Transport stream 1 (the layered data 1 and the layered data 2) & transport stream 2 (the layered data 3 and the layered data 4): A resource for the transport stream 1 is Res_{1,1}+Res_{1,2}, a resource for the transport stream 2 is Res_{2,3}+Res_{2,4}, and a resource difference percentage of the two transport streams is Diff₂=|1−(Res_{1,1}+Res_{1,2})/(Res_{2,3}+Res_{2,4})|.

Transport stream 1 (the layered data 1) & transport stream 2 (the layered data 2 to the layered data 4): A resource for the transport stream 1 is Res_{1,1}+Res_{1,2}+Res_{1,3}, a resource for the transport stream 2 is Res_{2,4}, and a resource difference percentage of the two transport streams is Diff₃=|1−(Res_{1,1}+Res_{1,2}+Res_{1,3})/Res_{2,4}|.

The network device may select a configuration manner that is for the MCS of each layer of data and bitstream grouping (or transport stream division) and that corresponds to a smallest value in Diff₁ to Diff₃, so that lengths of transmission resources for the two transport streams are closest.

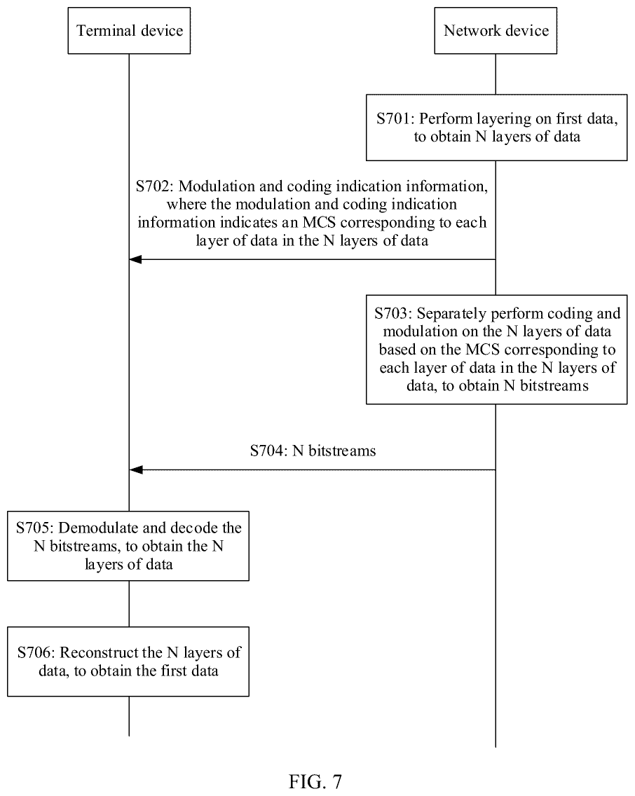

The foregoing mainly describes, from a perspective of uplink data transmission, performing UEP layered transmission on the to-be-transmitted first data. It may be understood that, for downlink data transmission, UEP layered transmission may also be used. FIG. 7 is a diagram of another communication method according to an embodiment of this application. The method includes the following steps.

S701: A network device performs layering on first data, to obtain N layers of data, where N is an integer greater than or equal to 2.

S702: The network device sends modulation and coding indication information to a terminal device, where the modulation and coding indication information indicates an MCS corresponding to each layer of data in the N layers of data. Correspondingly, the terminal device receives the modulation and coding indication information from the network device.

The MCS corresponding to each layer of data in the N layers of data is determined based on a ranking, in the N layers of data, of a source contribution degree of each layer of data in the N layers of data and a policy of mapping between a source contribution degree ranking and an MCS. The source contribution degree of each layer of data in the N layers of data indicates a deviation caused to the first data when the layer of data is missing.

S703: The network device separately performs coding and modulation on the N layers of data based on the MCS corresponding to each layer of data in the N layers of data, to obtain N bitstreams.

S704: The network device sends the N bitstreams to the network device. Correspondingly, the network device receives the N bitstreams.

S705: The terminal device demodulates and decodes the N bitstreams, to obtain the N layers of data.

S706: The terminal device reconstructs the N layers of data, to obtain the first data.

Implementation principles of the foregoing steps S701 to S706 are similar to implementation principles of the foregoing steps S201 to S206. For specific implementation, refer to the descriptions of S201 to S206. Details are not described again.

It should be understood that the communication method provided in this application is described above by using an example in which the first communication apparatus is a terminal device, the second communication apparatus is a network device, and the first data is transmitted between the terminal device and the network device. It may be understood that, in some implementations, the first communication apparatus is a terminal device, and the second communication apparatus may be a terminal device different from the first communication apparatus. The communication method provided in embodiments of this application is further applicable to transmission of first data between terminal devices.

It may be understood that, to implement functions in the foregoing embodiments, the first communication apparatus (for example, a terminal device) and the second communication apparatus (for example, a network device) include corresponding hardware structures and/or software modules for performing the functions. A person skilled in the art should be easily aware that, in combination with the units and the method steps in the examples described in embodiments disclosed in this application, this application can be implemented by using hardware or a combination of hardware and computer software. Whether a function is performed by using hardware or hardware driven by computer software depends on particular application scenarios and design constraints of the technical solutions.

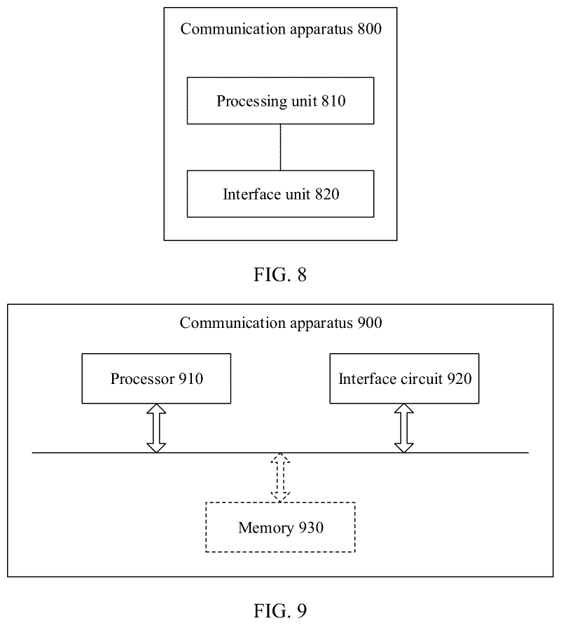

FIG. 8 and FIG. 9 are diagrams of structures of possible communication apparatuses according to an embodiment of this application. These communication apparatuses may be configured to implement functions of the first communication apparatus (for example, a terminal device) and the second communication apparatus (for example, a network device) in the foregoing method embodiments, and therefore can also implement beneficial effects of the foregoing method embodiments. In a possible implementation, the communication apparatus may be a terminal device or a network device, or may be a module (for example, a chip) used in the terminal device or the network device.

As shown in FIG. 8, a communication apparatus 800 includes a processing unit 810 and an interface unit 820. The interface unit 820 may alternatively be a transceiver unit or an input/output interface. The communication apparatus 800 may be configured to implement functions of the first communication apparatus (for example, a terminal device) and the second communication apparatus (for example, a network device) in the method embodiment shown in FIG. 2 or FIG. 7.

When the communication apparatus 800 is configured to implement the function of the first communication apparatus (for example, a terminal device) in the method embodiment shown in FIG. 2,
the processing unit 810 is configured to perform layering on first data, to obtain N layers of data, where N is an integer greater than or equal to 2; and the interface unit 820 is configured to receive modulation and coding indication information from a second communication apparatus, where the modulation and coding indication information indicates an MCS corresponding to each layer of data in P layers of data, the P layers of data belong to the N layers of data, the MCS corresponding to each layer of data in the P layers of data is determined based on a ranking of a source contribution degree of the layer of data in the P layers of data and a policy of mapping between a source contribution degree ranking and an MCS, the source contribution degree of each layer of data in the P layers of data indicates a deviation caused to the first data when the layer of data is missing, and P is less than or equal to N.

The processing unit 810 is further configured to separately perform coding and modulation on the P layers of data based on the MCS corresponding to each layer of data in the P layers of data, to obtain P bitstreams. The interface unit 820 is further configured to send N bitstreams to the second communication apparatus, where the N bitstreams include the P bitstreams and N—P bitstreams corresponding to N—P layers of data other than the P layers of data in the N layers of data.

In a possible design, the interface unit 820 is further configured to send source characteristic information to the second communication apparatus, where the source characteristic information includes the source contribution degree of each layer of data in the P layers of data.

In a possible design, when performing layering on the first data to obtain the N layers of data, the processing unit 810 is specifically configured to: determine, based on a first data type of the first data and an association relationship between a data type and a layering mode, a first layering mode associated with the first data type; and perform layering on the first data in the first layering mode, to obtain the N layers of data.

In a possible design, the deviation caused to the first data when each layer of data in the P layers of data is missing includes: one or more of a mean square error, a normalized mean square error, an imaging error, a positioning error, and an inference error caused to the first data when each layer of data in the P layers of data is missing.

In a possible design, that the MCS corresponding to each layer of data in the P layers of data is determined based on a ranking of a source contribution degree of the layer of data in the P layers of data and a policy of mapping between a source contribution degree ranking and an MCS includes: The MCS corresponding to each layer of data in the P layers of data is determined based on channel state information with the second communication apparatus, the ranking of the source contribution degree of the layer of data in the P layers of data, and a policy of mapping between an MCS and both channel state information and a source contribution degree ranking.

In a possible design, the interface unit 820 is further configured to: send data length information of each layer of data in the N layers of data to the second communication apparatus; and receive resource configuration information from the second communication apparatus, where the resource configuration information is used to configure M TBs for transmitting the N layers of data, and M is an integer greater than or equal to 1.

When sending the N bitstreams to the second communication apparatus, the interface unit 820 is specifically configured to send the N bitstreams to the second communication apparatus on the M TBs.

In a possible design, when a quantity O of transport streams for transmitting the N layers of data is greater than or equal to 2, during sending of the N bitstreams to the second communication apparatus on the M TBs, the interface unit 820 is specifically configured to: divide the N bitstreams into O groups of bitstreams based on sizes of the N bitstreams, where a difference between data volumes of the O groups of bitstreams is minimized; and respectively send the O groups of bitstreams to the second communication apparatus on the M TBs through the O transport streams.

In a possible design, the interface unit 820 is further configured to receive layer quantity indication information from the second communication apparatus, where the layer quantity indication information indicates N; or the processing unit 810 is further configured to determine N based on an unequal error protection UEP requirement for transmitting the first data.

In a possible design, MCSs corresponding to any two layers of data in the P layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

When the communication apparatus 800 is configured to implement the function of the second communication apparatus (for example, a network device) in the method embodiment shown in FIG. 2,
the processing unit 810 is configured to: obtain a source contribution degree of each layer of data in P layers of data in first data to be sent by a first communication apparatus, where the source contribution degree of each layer of data in the P layers of data indicates a deviation caused to the first data when the layer of data is missing; and determine modulation and coding indication information, where the modulation and coding indication information indicates a modulation and coding scheme MCS corresponding to each layer of data in the P layers of data, and the MCS corresponding to each layer of data in the P layers of data is determined based on a ranking of the source contribution degree of the layer of data in the P layers of data and a policy of mapping between a source contribution degree ranking and an MCS; and
the interface unit 820 is configured to send the modulation and coding indication information to the first communication apparatus.

In a possible design, the interface unit 820 is further configured to receive N bitstreams from the first communication apparatus, where the N bitstreams correspond to N layers of data in the first data, the N layers of data include the P layers of data, the N bitstreams include P bitstreams corresponding to the P layers of data and N—P bitstreams corresponding to N—P layers of data other than the P layers of data in the N layers of data, N is an integer greater than or equal to 2, and P is less than or equal to N; and the processing unit 810 is further configured to: demodulate and decode the N bitstreams, to obtain the N layers of data, where the P bitstreams corresponding to the P layers of data in the N bitstreams are demodulated and decoded based on the MCS corresponding to each layer of data in the P layers of data; and reconstruct the N layers of data, to obtain the first data.

In a possible design, when obtaining the source contribution degree of each layer of data in the P layers of data in the first data to be sent by the first communication apparatus, the processing unit 810 is specifically configured to receive source characteristic information from the first communication apparatus through the interface unit 820, where the source characteristic information includes the source contribution degree of each layer of data in the P layers of data.

In a possible design, the deviation caused to the first data when each layer of data in the P layers of data is missing includes: one or more of a mean square error, a normalized mean square error, an imaging error, a positioning error, and an inference error caused to the first data when each layer of data in the P layers of data is missing.

In a possible design, that the MCS corresponding to each layer of data in the P layers of data is determined based on a ranking of the source contribution degree of the layer of data in the P layers of data and a policy of mapping between a source contribution degree ranking and an MCS includes: The MCS corresponding to each layer of data in the P layers of data is determined based on channel state information with the first communication apparatus, the ranking of the source contribution degree of the layer of data in the P layers of data, and a policy of mapping between an MCS and both channel state information and a source contribution degree ranking.

In a possible design, the interface unit 820 is further configured to receive data length information of each layer of data in the N layers of data from the first communication apparatus; and the processing unit 810 is further configured to: determine, based on the data length information of each layer of data in the N layers of data, the MCS corresponding to each layer of data in the P layers of data in the N layers of data, and MCSs corresponding to the N—P layers of data, sizes of the N bitstreams corresponding to the N layers of data; and determine, based on the sizes of the N bitstreams corresponding to the N layers of data and a quantity O of transport streams for transmitting the N layers of data, M transport blocks TBs for transmitting the N layers of data, where M and O are integers greater than or equal to 1.

The interface unit 820 is further configured to send resource configuration information to the first communication apparatus, where the resource configuration information is used to configure the M TBs. When receiving the N bitstreams from the first communication apparatus, the interface unit 820 is specifically configured to receive the N bitstreams from the first communication apparatus on the M TBs.

In a possible design, when determining, based on the sizes of the N bitstreams corresponding to the N layers of data and the quantity O of transport streams for transmitting the N layers of data, the M TBs for transmitting the N layers of data, the processing unit 810 is specifically configured to: divide the N bitstreams into O groups of bitstreams based on the sizes of the N bitstreams corresponding to the N layers of data, where a difference between data volumes of the O groups of bitstreams is minimized; and determine, based on a data volume of a group of bitstreams corresponding to a largest data volume in the O groups of bitstreams, the M TBs for transmitting the N layers of data.

In a possible design, the processing unit 810 is further configured to determine N based on an unequal error protection UEP requirement for transmitting the first data by the first communication apparatus; and the interface unit 820 is further configured to send layer quantity indication information to the first communication apparatus, where the layer quantity indication information indicates N.

In a possible design, MCSs corresponding to any two layers of data in the P layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

When the communication apparatus 800 is configured to implement the function of the first communication apparatus (for example, a terminal device) in the method embodiment shown in FIG. 7,
the interface unit 820 is configured to: receive modulation and coding indication information from a second communication apparatus, where the modulation and coding indication information indicates an MCS corresponding to each layer of data in N layers of data to be sent by the second communication apparatus; and receive N bitstreams that are from the second communication apparatus and that are corresponding to the N layers of data; and the processing unit 810 is configured to: separately demodulate and decode the N bitstreams based on the MCS corresponding to each layer of data in the N layers of data, to obtain the N layers of data; and reconstruct the N layers of data, to obtain first data.

In a possible design, the interface unit 820 is further configured to receive resource configuration information from the second communication apparatus, where the resource configuration information is used to configure M TBs for transmitting the N layers of data, and M is an integer greater than or equal to 1; and when receiving the N bitstreams that are from the second communication apparatus and that are corresponding to the N layers of data, the interface unit 820 is specifically configured to receive the N bitstreams from the second communication apparatus on the M TBs.

In a possible design, MCSs corresponding to any two layers of data in the N layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

When the communication apparatus 800 is configured to implement the function of the second communication apparatus (for example, a network device) in the method embodiment shown in FIG. 7,
the processing unit 810 is configured to: perform layering on first data, to obtain N layers of data, where N is an integer greater than or equal to 2; and obtain a source contribution degree of each layer of data in the N layers of data, where the source contribution degree of each layer of data in the N layers of data indicates a deviation caused to the first data when the layer of data is missing;
the interface unit 820 is configured to send modulation and coding indication information to a first communication apparatus, where the modulation and coding indication information indicates an MCS corresponding to each layer of data in the N layers of data, and the MCS corresponding to each layer of data in the N layers of data is determined based on a ranking, in the N layers of data, of the source contribution degree of the layer of data in the N layers of data and a policy of mapping between a source contribution degree ranking and an MCS; and
the processing unit 810 is further configured to separately perform coding and modulation on the N layers of data based on the MCS corresponding to each layer of data in the N layers of data, to obtain N bitstreams; and the interface unit 820 is further configured to send the N bitstreams to the first communication apparatus.

In a possible design, when performing layering on the first data to obtain the N layers of data, the interface unit 820 is specifically configured to: determine, based on a first data type of the first data and an association relationship between a data type and a layering mode, a first layering mode associated with the first data type; and perform layering on the first data in the first layering mode, to obtain the N layers of data.

In a possible design, the deviation caused to the first data when each layer of data in the N layers of data is missing includes: one or more of a mean square error, a normalized mean square error, an imaging error, a positioning error, and an inference error caused to the first data when each layer of data in the N layers of data is missing.

In a possible design, the processing unit 810 is further configured to: determine, based on data length information of each layer of data in the N layers of data and the MCS corresponding to each layer of data in the N layers of data, sizes of the N bitstreams corresponding to the N layers of data; and determine, based on the sizes of the N bitstreams corresponding to the N layers of data and a quantity O of transport streams for transmitting the N layers of data, M TBs for transmitting the N layers of data, where M and O are integers greater than or equal to 1. The interface unit 820 is further configured to send resource configuration information to the first communication apparatus, where the resource configuration information is used to configure the M TBs. When sending the N bitstreams to the first communication apparatus, the interface unit 820 is specifically configured to send the N bitstreams to the second communication apparatus on the M TBs.

In a possible design, when the quantity O of transport streams for transmitting the N layers of data is greater than or equal to 2, during sending of the N bitstreams to the first communication apparatus on the M TBs, the interface unit 820 is specifically configured to: divide the N bitstreams into O groups of bitstreams based on sizes of the N bitstreams, where a difference between data volumes of the O groups of bitstreams is minimized; and respectively send the O groups of bitstreams to the first communication apparatus on the M TBs through the O transport streams.

In a possible design, determining, based on the ranking, in the N layers of data, of the source contribution degree of each layer of data in the N layers of data and the policy of mapping between a source contribution degree ranking and an MCS, the MCS corresponding to each layer of data in the N layers of data includes: determining, based on channel state information with the first communication apparatus, the ranking, in the N layers of data, of the source contribution degree of each layer of data in the N layers of data, and a policy of mapping between an MCS and both channel state information and a source contribution degree ranking, the MCS corresponding to each layer of data in the N layers of data.

In a possible design, MCSs corresponding to any two layers of data in the N layers of data satisfy: A code rate of an MCS corresponding to layer-A data is less than or equal to a code rate of an MCS corresponding to layer-B data; and/or a modulation order of the MCS corresponding to the layer-A data is less than or equal to a modulation order of the MCS corresponding to the layer-B data, where the layer-A data is layered data corresponding to a larger source contribution degree in the two layers of data, and the layer-B data is layered data corresponding to a smaller source contribution degree in the two layers of data.

As shown in FIG. 9, this application further provides a communication apparatus 900, including a processor 910 and an interface circuit 920. The processor 910 and the interface circuit 920 are coupled to each other. It may be understood that the interface circuit 920 may be a transceiver, an input/output interface, an input interface, an output interface, a communication interface, or the like. Optionally, the communication apparatus 900 may further include a memory 930, configured to: store instructions executed by the processor 910, or store input data required for running instructions by the processor 910, or store data generated after the processor 910 runs instructions. Optionally, the memory 930 may alternatively be integrated with the processor 910.

When the communication apparatus 900 is configured to implement the method shown in FIG. 7, the processor 910 may be configured to implement a function of the processing unit 810, and the interface circuit 920 may be configured to implement a function of the interface unit 820.

It may be understood that, the processor in embodiments of this application may be a central processing unit (central processing unit, CPU), or may be another general-purpose processor, a digital signal processor (digital signal processor, DSP), an application-specific integrated circuit (application-specific integrated circuit, ASIC), a logic circuit, a field programmable gate array (field programmable gate array, FPGA) or another programmable logic device, a transistor logic device, a hardware component, or any combination thereof. The general-purpose processor may be a microprocessor, or may be any conventional processor or the like.

The method steps in embodiments of this application may be implemented in a hardware manner, or may be implemented in a manner of executing software instructions by the processor. The software instructions may include a corresponding software module. The software module may be stored in a random access memory, a flash memory, a read-only memory, a programmable read-only memory, an erasable programmable read-only memory, an electrically erasable programmable read-only memory, a register, a hard disk, a removable hard disk, a CD-ROM, or any other form of storage medium well-known in the art. An example storage medium is coupled to a processor, so that the processor can read information from the storage medium and can write information into the storage medium. Certainly, the storage medium may alternatively be a part of the processor. The processor and the storage medium may be located in an ASIC. In addition, the ASIC may be located in a network device or a terminal device. Certainly, the processor and the storage medium may exist in the network device or the terminal device as discrete components.

All or some of the foregoing embodiments may be implemented by software, hardware, firmware, or any combination thereof. When software is used to implement the embodiments, all or some of the embodiments may be implemented in a form of a computer program product. The computer program product includes one or more computer programs or instructions. When the computer programs or the instructions are loaded and executed on a computer, all or some of the procedures or functions in embodiments of this application are executed. The computer may be a general-purpose computer, a dedicated computer, a computer network, a network device, user equipment, or another programmable apparatus. The computer programs or the instructions may be stored in a computer-readable storage medium or may be transmitted from a computer-readable storage medium to another computer-readable storage medium. For example, the computer programs or the instructions may be transmitted from a network device, terminal, computer, server, or data center to another network device, terminal, computer, server, or data center in a wired or wireless manner. The computer-readable storage medium may be any usable medium accessible by a computer, or a data storage device such as a server or a data center integrating one or more usable media. The usable medium may be a magnetic medium, for example, a floppy disk, a hard disk drive, or a magnetic tape; or may be an optical medium, for example, a digital video disc; or may be a semiconductor medium, for example, a solid-state drive. The computer-readable storage medium may be a volatile or non-volatile storage medium, or may include two types of storage media: a volatile storage medium and a non-volatile storage medium.

In embodiments of this application, unless otherwise stated or there is a logic conflict, terms and/or descriptions between different embodiments are consistent and may be mutually referenced, and technical features in different embodiments may be combined into a new embodiment based on an internal logical relationship thereof.

In addition, it should be understood that in embodiments of this application, the term “for example” is used to represent giving an example, an illustration, or a description. Any embodiment or design scheme described as an “example” in this application should not be explained as being more preferred or having more advantages than another embodiment or design scheme. Specifically, the term “example” is used to present a concept in a specific manner.

It may be understood that various numbers in embodiments of this application are merely used for differentiation for ease of description, and are not used to limit the scope of embodiments of this application. Sequence numbers of the foregoing processes do not mean a sequence of execution. The sequence of execution of the processes should be determined according to functions and internal logic of the processes.

What is claimed is:

1. A communication method, comprising:
performing layering on first data, to obtain N layers of data, wherein N is an integer greater than or equal to 2;
receiving modulation and coding indication information from a second communication apparatus, wherein the modulation and coding indication information indicates a modulation and coding scheme MCS corresponding to each layer of data in P layers of data, the P layers of data belong to the N layers of data, the MCS corresponding to each layer of data in the P layers of data is determined based on a ranking of a source contribution degree of the layer of data in the P layers of data and a policy of mapping between a source contribution degree ranking and an MCS, the source contribution degree of each layer of data in the P layers of data indicates a deviation caused to the first data when the layer of data is missing, and P is less than or equal to N;
separately performing coding and modulation on the P layers of data based on the MCS corresponding to each layer of data in the P layers of data, to obtain P bitstreams; and
sending N bitstreams to the second communication apparatus, wherein the N bitstreams comprise the P bitstreams and N—P bitstreams corresponding to N—P layers of data other than the P layers of data in the N layers of data.

2. The method according to claim 1, wherein the method further comprises:
sending source characteristic information to the second communication apparatus, wherein the source characteristic information comprises the source contribution degree of each layer of data in the P layers of data.

3. The method according to claim 1, wherein the performing layering on first data, to obtain N layers of data comprises:
determining, based on a first data type of the first data and an association relationship between a data type and a layering mode, a first layering mode associated with the first data type; and
performing layering on the first data in the first layering mode, to obtain the N layers of data.

4. The method according to claim 1, wherein the deviation caused to the first data when each layer of data in the P layers of data is missing comprises:
one or more of a mean square error, a normalized mean square error, an imaging error, a positioning error, and an inference error caused to the first data when each layer of data in the P layers of data is missing.

5. The method according to claim 1, wherein that the MCS corresponding to each layer of data in the P layers of data is determined based on a ranking of a source contribution degree of the layer of data in the P layers of data and a policy of mapping between a source contribution degree ranking and an MCS comprises:
the MCS corresponding to each layer of data in the P layers of data is determined based on channel state information with the second communication apparatus, the ranking of the source contribution degree of the layer of data in the P layers of data, and a policy of mapping between an MCS and both channel state information and a source contribution degree ranking.

6. The method according to claim 1, wherein the method further comprises:
sending data length information of each layer of data in the N layers of data to the second communication apparatus; and
receiving resource configuration information from the second communication apparatus, wherein the resource configuration information is used to configure M transport blocks TBs for transmitting the N layers of data, and M is an integer greater than or equal to 1; and
the sending N bitstreams to the second communication apparatus comprises:
sending the N bitstreams to the second communication apparatus on the M TBs.

7. The method according to claim 6, wherein when a quantity O of transport streams for transmitting the N layers of data is greater than or equal to 2, the sending the N bitstreams to the second communication apparatus on the M TBs comprises:
dividing the N bitstreams into O groups of bitstreams based on sizes of the N bitstreams, wherein a difference between data volumes of the O groups of bitstreams is minimized; and
respectively sending the O groups of bitstreams to the second communication apparatus on the M TBs through the O transport streams.

8. The method according to claim 1, wherein the method further comprises:
receiving layer quantity indication information from the second communication apparatus, wherein the layer quantity indication information indicates N; or
determining N based on an unequal error protection UEP requirement for transmitting the first data.

9. The method according to claim 1, wherein MCSs corresponding to any two layers of data in the P layers of data satisfy:
a code rate of an MCS corresponding to layer-A data is less than or equal to a code rate of an MCS corresponding to layer-B data; and/or
a modulation order of the MCS corresponding to the layer-A data is less than or equal to a modulation order of the MCS corresponding to the layer-B data, wherein
the layer-A data is layered data corresponding to a larger source contribution degree in the two layers of data, and the layer-B data is layered data corresponding to a smaller source contribution degree in the two layers of data.

10. A communication method, comprising:
obtaining a source contribution degree of each layer of data in P layers of data in first data to be sent by a first communication apparatus, wherein the source contribution degree of each layer of data in the P layers of data indicates a deviation caused to the first data when the layer of data is missing; and
sending modulation and coding indication information to the first communication apparatus, wherein the modulation and coding indication information indicates a modulation and coding scheme MCS corresponding to each layer of data in the P layers of data, and the MCS corresponding to each layer of data in the P layers of data is determined based on a ranking of the source contribution degree of the layer of data in the P layers of data and a policy of mapping between a source contribution degree ranking and an MCS.

11. The method according to claim 10, wherein the method further comprises:
receiving N bitstreams from the first communication apparatus, wherein the N bitstreams correspond to N layers of data in the first data, the N layers of data comprise the P layers of data, the N bitstreams comprise P bitstreams corresponding to the P layers of data and N—P bitstreams corresponding to N—P layers of data other than the P layers of data in the N layers of data, N is an integer greater than or equal to 2, and P is less than or equal to N;
demodulating and decoding the N bitstreams, to obtain the N layers of data, wherein the P bitstreams corresponding to the P layers of data in the N bitstreams are demodulated and decoded based on the MCS corresponding to each layer of data in the P layers of data; and
reconstructing the N layers of data, to obtain the first data.

12. The method according to claim 10, wherein the obtaining a source contribution degree of each layer of data in P layers of data to be sent by a first communication apparatus comprises:
receiving source characteristic information from the first communication apparatus, wherein the source characteristic information comprises the source contribution degree of each layer of data in the P layers of data.

13. The method according to claim 11, wherein the deviation caused to the first data when each layer of data in the P layers of data is missing comprises:
one or more of a mean square error, a normalized mean square error, an imaging error, a positioning error, and an inference error caused to the first data when each layer of data in the P layers of data is missing.

14. The method according to claim 10, wherein that the MCS corresponding to each layer of data in the P layers of data is determined based on a ranking of the source contribution degree of the layer of data in the P layers of data and a policy of mapping between a source contribution degree ranking and an MCS comprises:
the MCS corresponding to each layer of data in the P layers of data is determined based on channel state information with the first communication apparatus, the ranking of the source contribution degree of the layer of data in the P layers of data, and a policy of mapping between an MCS and both channel state information and a source contribution degree ranking.

15. The method according to claim 11, wherein the method further comprises:
receiving data length information of each layer of data in the N layers of data from the first communication apparatus;
determining, based on the data length information of each layer of data in the N layers of data, the MCS corresponding to each layer of data in the P layers of data in the N layers of data, and MCSs corresponding to the N—P layers of data, sizes of the N bitstreams corresponding to the N layers of data;
determining, based on the sizes of the N bitstreams corresponding to the N layers of data and a quantity O of transport streams for transmitting the N layers of data, M transport blocks TBs for transmitting the N layers of data, wherein M and O are integers greater than or equal to 1; and
sending resource configuration information to the first communication apparatus, wherein the resource configuration information is used to configure the M TBs; and
the receiving N bitstreams from the first communication apparatus comprises:
receiving the N bitstreams from the first communication apparatus on the M TBs.

16. The method according to claim 15, wherein the determining, based on the sizes of the N bitstreams corresponding to the N layers of data and a quantity O of transport streams for transmitting the N layers of data, M TBs for transmitting the N layers of data comprises:
dividing the N bitstreams into O groups of bitstreams based on the sizes of the N bitstreams corresponding to the N layers of data, wherein a difference between data volumes of the O groups of bitstreams is minimized; and
determining, based on a data volume of a group of bitstreams corresponding to a largest data volume in the O groups of bitstreams, the M TBs for transmitting the N layers of data.

17. The method according to claim 10, wherein the method further comprises:
determining N based on an unequal error protection UEP requirement for transmitting the first data by the first communication apparatus; and
sending layer quantity indication information to the first communication apparatus, wherein the layer quantity indication information indicates N.

18. The method according to claim 10, wherein MCSs corresponding to any two layers of data in the P layers of data satisfy:
a code rate of an MCS corresponding to layer-A data is less than or equal to a code rate of an MCS corresponding to layer-B data; and/or
a modulation order of the MCS corresponding to the layer-A data is less than or equal to a modulation order of the MCS corresponding to the layer-B data, wherein
the layer-A data is layered data corresponding to a larger source contribution degree in the two layers of data, and the layer-B data is layered data corresponding to a smaller source contribution degree in the two layers of data.

19. A communication apparatus, comprising an interface unit and a processing unit, wherein
the processing unit is configured to perform layering on first data, to obtain N layers of data, wherein N is an integer greater than or equal to 2;
the interface unit is configured to receive modulation and coding indication information from a second communication apparatus, wherein the modulation and coding indication information indicates a modulation and coding scheme MCS corresponding to each layer of data in P layers of data, the P layers of data belong to the N layers of data, the MCS corresponding to each layer of data in the P layers of data is determined based on a ranking of a source contribution degree of the layer of data in the P layers of data and a policy of mapping between a source contribution degree ranking and an MCS, the source contribution degree of each layer of data in the P layers of data indicates a deviation caused to the first data when the layer of data is missing, and P is less than or equal to N;
the processing unit is further configured to separately perform coding and modulation on the P layers of data based on the MCS corresponding to each layer of data in the P layers of data, to obtain P bitstreams; and
the interface unit is further configured to send N bitstreams to the second communication apparatus, wherein the N bitstreams comprise the P bitstreams and N—P bitstreams corresponding to N—P layers of data other than the P layers of data in the N layers of data.

20. The apparatus according to claim 19, wherein the interface unit is further configured to send source characteristic information to the second communication apparatus, wherein the source characteristic information comprises the source contribution degree of each layer of data in the P layers of data.
